(19) United States
(12) Patent Application Publication
(10) Pub. No.: US 2026/0290407 A1
(43) Pub. Date: Sep. 24, 2026

(54) SEMICONDUCTOR MEMORY DEVICE AND METHOD OF MANUFACTURING SEMICONDUCTOR MEMORY DEVICE

(71) Applicant: Kioxia Corporation, Tokyo (JP)

(72) Inventor: Kaiki YO, Yokkaichi Mie (JP)

(73) Assignee: Kioxia Corporation, Tokyo (JP)

(21) Appl. No.: 19/323,721

(22) Filed: Sep. 9, 2025

(30) Foreign Application Priority Data
Mar. 21, 2025 (JP) 2025-047164

(51) Int. Cl. G11C 5/06; G11C 16/04; H10B 43/10; H10B 43/27; H10B 43/35; H10D 30/01; H10D 30/69

(52) U.S. Cl. CPC G11C 5/063; G11C 16/0483; H10B 43/10; H10B 43/27; H10B 43/35; H10D 30/0413; H10D 30/693

(57) ABSTRACT

According to one embodiment, a semiconductor memory device includes a plurality of contact plugs corresponding to a plurality of second insulating layers. Each of the contact plugs extends in the third direction in the second region and reaches a stacking position of a corresponding second insulating layer. The plurality of first conductive lines corresponds to the plurality of second insulating layers. Each of the first conductive lines extends in the first direction along a first side surface of a corresponding second insulating layer in the second region. The plurality of second conductive lines corresponds to the plurality of second insulating layers. Each of the second conductive lines extends in the first direction along a second side surface of a corresponding second insulating layer in the second region. The second side surface is on an opposite side of the first side surface.

### CROSS-REFERENCE TO RELATED APPLICATIONS

This application is based upon and claims the benefit of Japanese Patent Application No. 2025-047164, filed on Mar. 21, 2025; the entire contents of which are incorporated herein by reference.

### FIELD

Embodiments described herein relate generally to a semiconductor memory device and a method of manufacturing a semiconductor memory device.

### BACKGROUND

In a semiconductor memory device having a stacked body in which a plurality of conductive layers is stacked via an insulating layer, in order to make the plurality of conductive layers electrically accessible, a plurality of contact plugs each extending in a stacking direction and electrically connected to a corresponding conductive layer among the plurality of conductive layers is provided. In the semiconductor memory device, it is desired that the contact plugs are easily processed.

### BRIEF DESCRIPTION OF THE DRAWINGS

FIG. 1 is a perspective view illustrating an overview configuration of a semiconductor memory device according to an embodiment;

FIG. 2 is a block diagram illustrating an overview configuration of the semiconductor memory device according to the embodiment;

FIG. 3 is a circuit diagram illustrating a configuration of a memory cell array according to the embodiment;

FIG. 4 is a cross-sectional view illustrating a configuration of the memory cell array according to the embodiment;

FIG. 5 is a plan view illustrating a configuration of the memory cell according to the embodiment;

FIG. 6 is a cross-sectional view illustrating a schematic configuration of a stacked body according to the embodiment;

FIG. 7 is a plan view illustrating a schematic configuration of the stacked body according to the embodiment;

FIG. 8 is a perspective view illustrating a schematic configuration of a contact region according to the embodiment;

FIGS. 9A to 9C are cross-sectional views illustrating a configuration of a contact region according to the embodiment;

FIG. 10 is a sectional view illustrating a configuration of a contact region according to the embodiment;

FIG. 11 is a plan view illustrating signal transmission from the contact region to a memory cell array region according to the embodiment;

FIG. 12 is a plan view illustrating a configuration of a contact region according to a first modification of the embodiment;

FIG. 13 is a cross-sectional illustrating a configuration of a contact region according to the first modification of the embodiment;

FIG. 14 is a plan view illustrating a configuration of a contact region according to a second modification of the embodiment;

FIG. 15 is a cross-sectional illustrating a configuration of a contact region according to the second modification of the embodiment;

FIG. 16 is a plan view illustrating a configuration of a contact region according to a third modification of the embodiment;

FIG. 17 is a cross-sectional illustrating a configuration of a contact region according to the third modification of the embodiment;

FIG. 18 is a plan view illustrating a configuration of a contact region according to a fourth modification of the embodiment;

FIG. 19 is a plan view illustrating a schematic configuration of a stacked body according to a fifth modification of the embodiment;

FIG. 20 is a cross-sectional view illustrating a configuration of a contact region according to the fifth modification of the embodiment;

FIG. 21 is a cross-sectional view illustrating a configuration of the contact region according to the fifth modification of the embodiment;

FIG. 22 is a plan view illustrating a schematic configuration of a stacked body according to a sixth modification of the embodiment;

FIGS. 23A to 23D are a plan view and a cross-sectional view illustrating a method of manufacturing a semiconductor memory device according to a seventh modification of the embodiment;

FIGS. 24A to 24D are a plan view and a cross-sectional view illustrating the method of manufacturing the semiconductor memory device according to the seventh modification of the embodiment;

FIGS. 25A to 25D are a plan view and a cross-sectional view illustrating the method of manufacturing the semiconductor memory device according to the seventh modification of the embodiment;

FIGS. 26A to 26D are a plan view and a cross-sectional view illustrating the method of manufacturing the semiconductor memory device according to the seventh modification of the embodiment;

FIGS. 27A to 27D are a plan view and a cross-sectional view illustrating the method of manufacturing the semiconductor memory device according to the seventh modification of the embodiment;

FIGS. 28A to 28D are a plan view and a cross-sectional view illustrating the method of manufacturing the semiconductor memory device according to the seventh modification of the embodiment;

FIGS. 29A to 29D are a plan view and a cross-sectional view illustrating the method of manufacturing the semiconductor memory device according to the seventh modification of the embodiment;

FIGS. 30A to 30D are a plan view and a cross-sectional view illustrating the method of manufacturing the semiconductor memory device according to the seventh modification of the embodiment;

FIGS. 31A to 31D are a plan view and a cross-sectional view illustrating the method of manufacturing the semiconductor memory device according to the seventh modification of the embodiment;

FIGS. 32A to 32D are a plan view and a cross-sectional view illustrating the method of manufacturing the semiconductor memory device according to the seventh modification of the embodiment;

FIG. 33 is a plan view illustrating the method of manufacturing the semiconductor memory device according to the seventh modification of the embodiment;

FIGS. 34A to 34D are a plan view and a cross-sectional view illustrating the method of manufacturing the semiconductor memory device according to the seventh modification of the embodiment;

FIG. 35 is a plan view illustrating the method of manufacturing the semiconductor memory device according to the seventh modification of the embodiment;

FIGS. 36A to 36D are a plan view and a cross-sectional view illustrating the method of manufacturing the semiconductor memory device according to the seventh modification of the embodiment;

FIG. 37 is a plan view illustrating the method of manufacturing the semiconductor memory device according to the seventh modification of the embodiment;

FIGS. 38A to 38D are a plan view and a cross-sectional view illustrating the method of manufacturing the semiconductor memory device according to the seventh modification of the embodiment;

FIG. 39 is a plan view illustrating the method of manufacturing the semiconductor memory device according to the seventh modification of the embodiment;

FIGS. 40A to 40D are plan views illustrating the method of manufacturing the semiconductor memory device according to the seventh modification of the embodiment; and

FIG. 41 is a plan view and a cross-sectional view illustrating the method of manufacturing the semiconductor memory device according to the seventh modification of the embodiment.

### DETAILED DESCRIPTION

In general, according to one embodiment, a semiconductor memory device including a stacked body, a semiconductor film, a charge storage film, a plurality of contact plugs, a plurality of first conductive lines, and a plurality of second conductive lines is provided. The stacked body has a first region and a second region. The second region is adjacent to the first region in a first direction. In the stacked body, a plurality of conductive layers is stacked in a third direction via a first insulating layer in the first region. The third direction intersects the first direction and the second direction. In the stacked body, a plurality of second insulating layers is stacked in the third direction via the first insulating layer in the second region. The semiconductor film extends in the third direction in the first region. The charge storage film extends in the third direction between the plurality of conductive layers and the semiconductor film in the first region. The plurality of contact plugs corresponds to the plurality of second insulating layers. Each of the contact plugs extends in the third direction in the second region and reaches a stacking position of a corresponding second insulating layer. The plurality of first conductive lines corresponds to the plurality of second insulating layers. Each of the first conductive lines extends in the first direction along a first side surface of a corresponding second insulating layer in the second region. The plurality of second conductive lines corresponds to the plurality of second insulating layers. Each of the second conductive lines extends in the first direction along a second side surface of a corresponding second insulating layer in the second region. The second side surface is on an opposite side of the first side surface.

Exemplary embodiments of a semiconductor memory device will be explained below in detail with reference to the accompanying drawings. The present invention is not limited to the following embodiments.

### Embodiment

A semiconductor memory device according to an embodiment includes a stacked body in which a plurality of conductive layers is stacked with an insulating layer interposed therebetween, and a plurality of contact plugs each extending in a stacking direction and electrically connected to a corresponding conductive layer among the plurality of conductive layers is provided. A measure is taken to facilitate processing of the contact plugs.

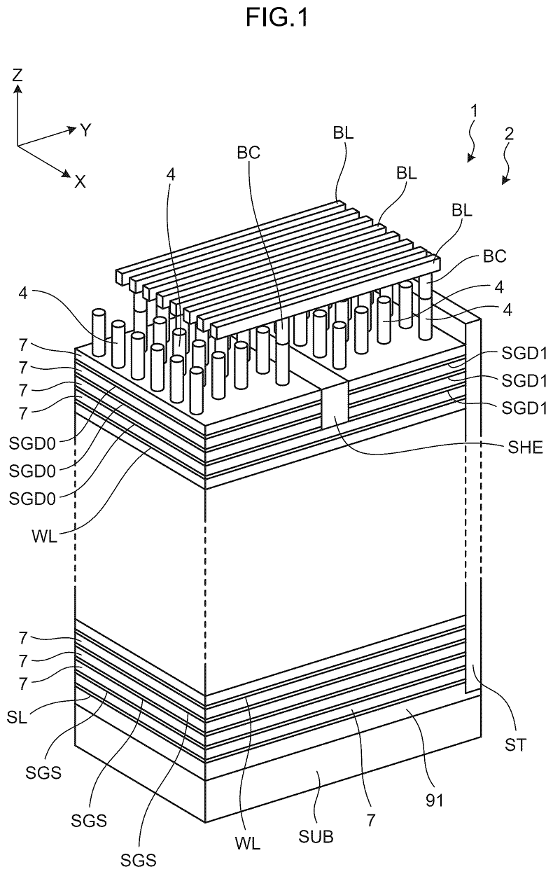

A semiconductor memory device 1 can be configured as illustrated in FIG. 1. FIG. 1 is a perspective view schematically illustrating a configuration of a memory cell array 2 included in the semiconductor memory device 1 according to the embodiment. The semiconductor memory device 1 may be a NAND nonvolatile memory including three-dimensionally arranged memory cells. Hereinafter, a direction perpendicular to a surface of a substrate SUB is referred to as a Z direction, and two directions orthogonal to each other in a plane perpendicular to the Z direction are referred to as an X direction and a Y direction.

As illustrated in FIG. 1, the semiconductor memory device 1 includes a source line SL, a selection gate SW, a word line WL, and a selection gate SGD. The source line SL is stacked, via an interlayer insulating film 91, on a +Z side of the substrate SUB via an insulating layer 7. The selection gate SW is stacked on the source line SL via the insulating layer 7. In an example in FIG. 1, three layers of selection gates SW are provided. A word line WL is stacked on an uppermost selection gate SW via the insulating layer 7. In the example in FIG. 1, the word lines WL are provided in a plurality of layers. The selection gate SGD is stacked on the uppermost word line WL via the insulating layer 7. In the example in FIG. 1, three layers of the selection gate SGD are provided. The selection gate SGD refers to a plurality of selection gates included in the same layer in a divided manner. In the example in FIG. 1, selection gates SGD0 and SGD1 divided in the Y direction are illustrated. The selection gate SGD is stacked on the uppermost word line WL via the insulating layer 7. The source line SL, the selection gate SW, the word line WL, and the selection gate SGD have a plate shape extending in the X direction and the Y direction, respectively.

In the example in FIG. 1, the selection gate SGD, the word line WL, and the selection gate SW are divided and insulated in the Y direction by a slit ST. The slit ST is provided in the substrate SUB and extends in the X direction and the Z direction.

The selection gate SGD is divided in the Y direction by, for example, an insulating film SHE. The insulating film SHE is provided above the word line WL (+Z side) and extends in the X direction and the Z direction. Therefore, on the word line WL, the selection gates SGD0 and the selection gates SGD1 are arranged side by side in the Y direction. In the example in FIG. 1, three layers of the selection gates SGD0 and SGD1 are provided.

The substrate SUB may be formed of a material containing a semiconductor, such as silicon, as a main component. Each of the selection gate SW, the word line WL, and the selection gate SGD may be made of a material containing metal, such as tungsten (W), as a main component. Each of the insulating layer 7 and the insulating film SHE can be formed of an insulator such as silicon oxide.

The semiconductor memory device 1 further includes a plurality of columnar bodies 4. The columnar bodies 4 penetrate the selection gate SW, the word line WL, and the selection gate SGD, and extend in the Z direction which is the stacking direction thereof. The semiconductor memory device 1 further includes a plurality of bit lines BL provided above the selection gate SGD and the source line SL.

The columnar bodies 4 are electrically connected to respective bit lines BL via a contact plug BC. FIG. 1 illustrates a configuration in which one of the columnar bodies 4 sharing the selection gate SGD0 and one of the columnar bodies 4 sharing the selection gate SGD1 are electrically connected to one of the plurality of bit lines BL via the contact plug BC.

In the case of a semiconductor memory device (memory) having a three-dimensional structure like the semiconductor memory device 1, a portion where the word line WL and the columnar body 4 intersect is configured to function as a memory cell, and the memory cell array 2 is configured with a plurality of memory cells three-dimensionally arranged. In addition, a portion where the selection gate SW and the columnar body 4 intersect functions as a source-side selection gate, and a portion where the selection gates SGD0 and SGD1 and the columnar body 4 intersect functions as a drain-side selection gate. In the semiconductor memory device 1, by increasing the number of stacked word lines WL in the stacked body, it is possible to increase a storage capacity without using a finer patterning technology.

It should be noted that in FIG. 1, the interlayer insulating film provided between the selection gate SGD and the bit line BL is omitted for simplification of illustration. Still more, FIG. 1 illustrates a configuration in which the substrate SUB is disposed on the opposite side of the bit lines BL with respect to the memory cell array 2. However, the substrate SUB may be disposed on the opposite side of the memory cell array 2 with respect to the bit lines BL.

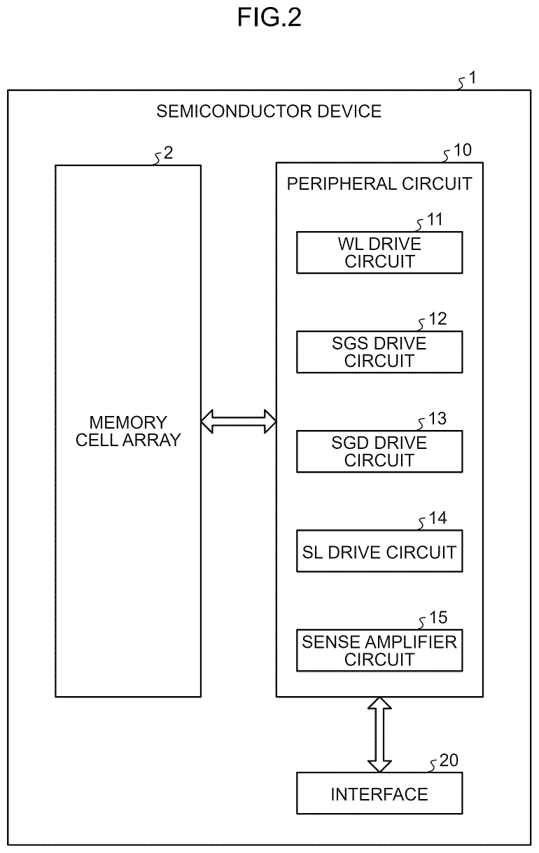

FIG. 2 is a block diagram illustrating a configuration of the semiconductor memory device 1.

As illustrated in FIG. 2, the semiconductor memory device 1 includes the memory cell array 2, a peripheral circuit 10, and an interface 20. The peripheral circuit 10 includes a WL drive circuit 11, an SW drive circuit 12, an SGD drive circuit 13, an SL drive circuit 14, and a sense amplifier circuit 15.

The WL drive circuit 11 is a circuit that controls a voltage applied to the word line WL, and the SW drive circuit 12 is a circuit that controls a voltage applied to the selection gate SW. The SGD drive circuit 13 is a circuit that controls a voltage applied to the selection gate SGD, and the SL drive circuit 14 is a circuit that controls a voltage applied to the source line SL. The sense amplifier circuit 15 is a circuit that determines data read according to a signal from a selected memory cell.

The peripheral circuit 10 controls the operation of the semiconductor memory device 1 based on an instruction input from outside (e.g., a memory controller of a memory system to which the semiconductor memory device 1 is applied) via the interface 20. For example, when a write instruction is received, the peripheral circuit 10 selects a memory cell of an address instructed to write from the SW drive circuit 12, the SGD drive circuit 13, and the WL drive circuit 11, and applies a voltage corresponding to data to the memory cell selected to write. Still more, when the read instruction is received, the peripheral circuit 10 selects a memory cell of an address instructed in the memory cell array 2 from the SW drive circuit 12, the SGD drive circuit 13, and the WL drive circuit 11, the sense amplifier circuit 15 determines the data read according to a signal from the memory cell selected, and the data is output to the outside (memory controller) via the interface 20.

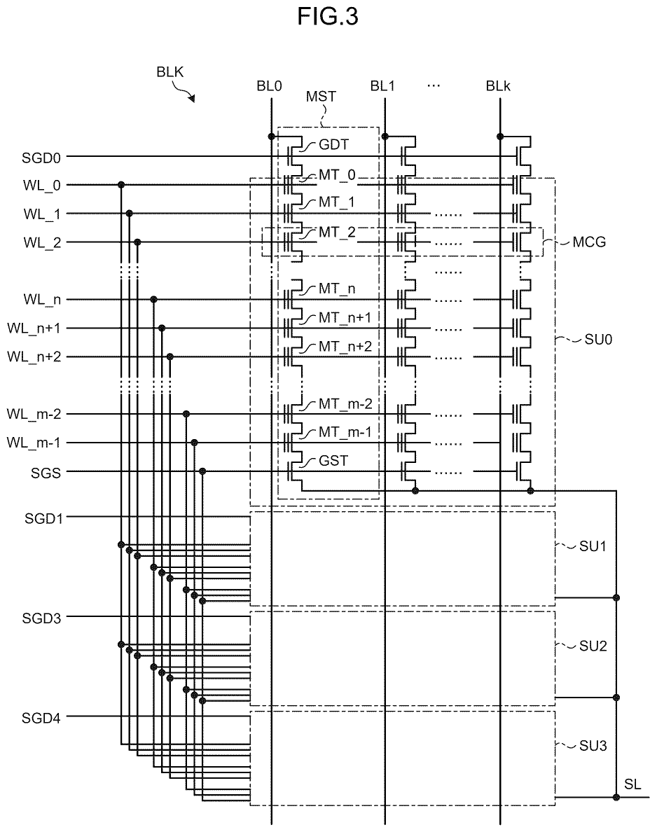

Next, a configuration of the memory cell array 2 will be described with reference to FIG. 3. FIG. 3 is a circuit diagram illustrating the configuration of the memory cell array 2 included in the semiconductor memory device 1.

The memory cell array 2 includes a plurality of blocks BLK each of which is a set of a plurality of memory cells MT. The memory cell MT is also referred to as a memory cell transistor.

Each of the blocks BLK includes a plurality of string units SU0, SU1, SU2, and SU3 that are the set of the memory cells MT associated with the word line WL and the bit line BL. Each of the string units SU0 to SU3 includes a plurality of memory strings MST in which the memory cells MT are connected in series. Note that the number of memory strings MST in the string units SU0 to SU3 is arbitrary.

The plurality of string units SU0, SU1, SU2, and SU3 corresponds to a plurality of selection gate lines SGD0, SGD1, SGD3, and SGD4, shares the word line WL, and functions as a plurality of drive units in the block BLK. Each of the string units SU can be driven by its corresponding selection gate line SGD and word line WL. Still more, each of the string units SU includes the plurality of memory strings MST.

Each of the memory strings MST includes, for example, m memory cells MT (MT_0 to MT_m−1) and selection transistors GDT and GST. m is an arbitrary integer of 2 or more. The m memory cells MT (MT_0 to MT_m−1) correspond to m word lines WL_1 to WL_m−1. The memory cell MT includes a control gate and a charge storage layer, and holds data in a nonvolatile manner. The m memory cells MT (MT_0 to MT_m−1) are connected in series between a source of the selection transistor GDT and a drain of the selection transistor GST.

A gate of the selection transistor GDT in each string unit SU is connected to the selection gate line SGD. On the other hand, a gate of the selection transistor GST in each string unit SU is commonly connected to, for example, the word line WL.

The drain of the selection transistor GDT of memory string MST in a respective string unit SU is connected to different bit lines BL0 to BLk (k is an arbitrary integer of two or more). In addition, the bit lines BL0 to BLk commonly connect one memory string MST in each string unit SU among the plurality of blocks BLK. Furthermore, a source of each of the selection transistors GST is commonly connected to the source line SL.

In other words, the string unit SU is a set of memory strings MST connected to different bit lines BL0 to BLk and connected to the same selection gate line SGD. The block BLK is a set of the plurality of string units SU0 to SU3 sharing the word line WL. The memory cell array 2 is a set of the plurality of blocks BLK sharing the bit lines BL0 to BLk.

When a group of memory cells MT sharing the word line WL is referred to as a “memory cell group MCG”, the memory cell group MCG is a minimum unit of a set of memory cells to which a predetermined voltage (e.g., a write voltage and a read voltage) can be collectively applied via the word line WL.

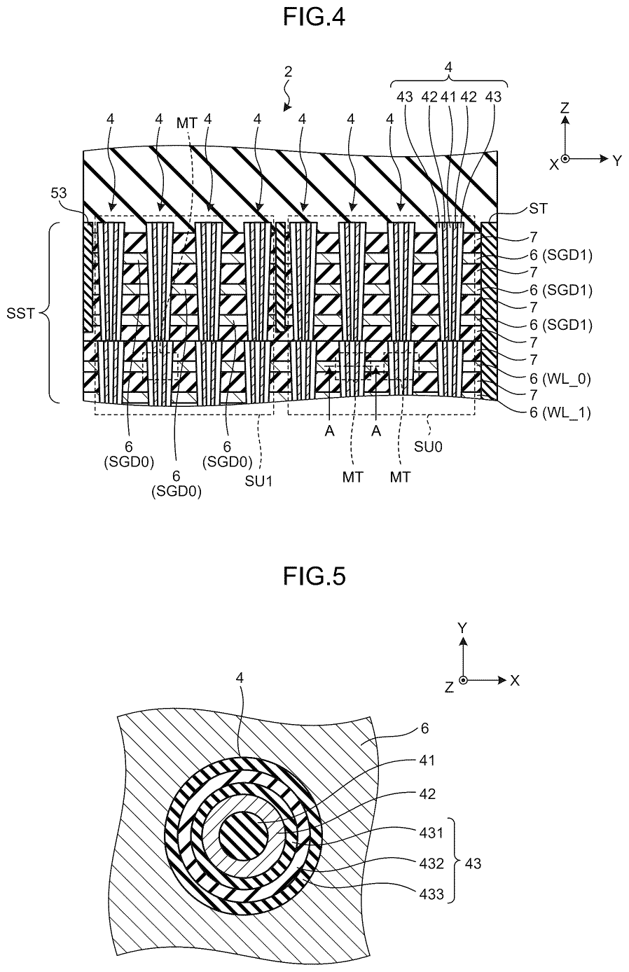

Next, a specific configuration of the memory cell array 2 will be described with reference to FIGS. 4 and 5. FIG. 4 is a ZY cross-sectional view illustrating a configuration of the memory cell array 2. FIG. 5 is an XY plan view illustrating a configuration of the memory cell MT, and illustrating an XY plane when FIG. 4 is cut along line A-A.

As illustrated in FIGS. 1, 4, and 5, in the memory cell array 2, the columnar bodies 4 are two-dimensionally arranged in the XY direction on the +Z side of the substrate SUB, and the word lines WL in a plurality of layers are penetrated by the columnar bodies 4 to form a three-dimensional array of the memory cells MT.

In the memory cell array 2, the conductive layer 6 and the insulating layer 7 are alternately and repeatedly stacked. In the memory cell array 2, each conductive layer 6 can be formed of a material containing a conductive material (e.g., metal such as tungsten) as a main component. Each insulating layer 7 can be formed of a material containing an insulator (e.g., semiconductor oxide such as silicon oxide) as a main component. Most of the conductive layers 6 function as the word line WL. The conductive layer 6 on the +Z-side functions as the selection gate line SGD. The conductive layer 6 on the −Z side functions as the word line WL and the source line SL.

In the memory cell array 2, a plurality of memory cells MT is configured at a plurality of positions where the plurality of word lines WL and the plurality of columnar bodies 4 intersect. A plurality of selection transistors GDT is formed at a plurality of positions where the selection gate line SGD intersects the plurality of columnar bodies 4. The plurality of selection transistors GST is formed at a plurality of positions where the word line WL intersects the plurality of columnar bodies 4. As illustrated in FIG. 5, the columnar body 4 includes a core insulating film 41, a semiconductor film 42, and an insulating film 43. The core insulating film 41 may be formed of a material containing an insulator (e.g., silicon oxide) as a main component. The semiconductor film 42 is disposed so as to surround the core insulating film 41 from the outside and has a substantially cylindrical shape extending along a central axis of the columnar body 4.

The semiconductor film 42 includes a channel region (active region) in the memory string MST, and can be formed of a material containing a semiconductor (e.g., polysilicon) as a main component.

The insulating film 43 is disposed between the conductive layer 6 and the semiconductor film 42, and surrounds the semiconductor film 42 in plan view. The insulating film 43 covers a side surface of the semiconductor film 42. The insulating film 43 is configured to have a charge accumulation capability in a portion disposed between the conductive layer 6 and the semiconductor film 42.

As illustrated in FIG. 5, the insulating film 43 may have a three-layer structure of a tunnel insulating film 431, a charge storage film 432, and a block insulating film 433 in order from the side of the semiconductor film 42. The tunnel insulating film 431 can be formed of a material containing oxide (e.g., silicon oxide) as a main component. The charge accumulation film 432 can be formed of a material containing nitride (e.g., silicon nitride) as a main component. The block insulating film 433 may be made of a material containing oxide (e.g., silicon oxide, metal oxide, or stacking thereof) as a main component.

In other words, the insulating film 43 may have an ONO type three-layer structure in which the charge storage film is sandwiched between a pair of insulating films (tunnel insulating film or block insulating film) in a portion (memory cell MT) disposed between the conductive layer 6 (word line WL) and the semiconductor film 42. Furthermore, the insulating film 43 may have a single-layer structure of a gate insulating film in a portion (selection transistor GDT) disposed between the conductive layer 6 (selection gate line SGD) and the semiconductor film 42. The gate insulating film may be made of a material containing oxide (e.g., silicon oxide) as a main component.

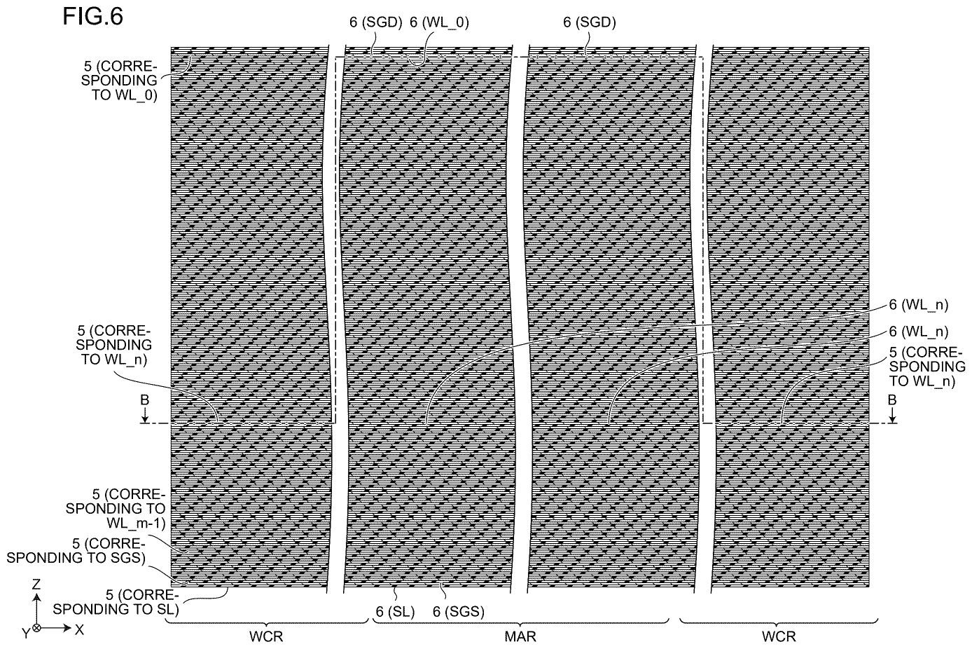

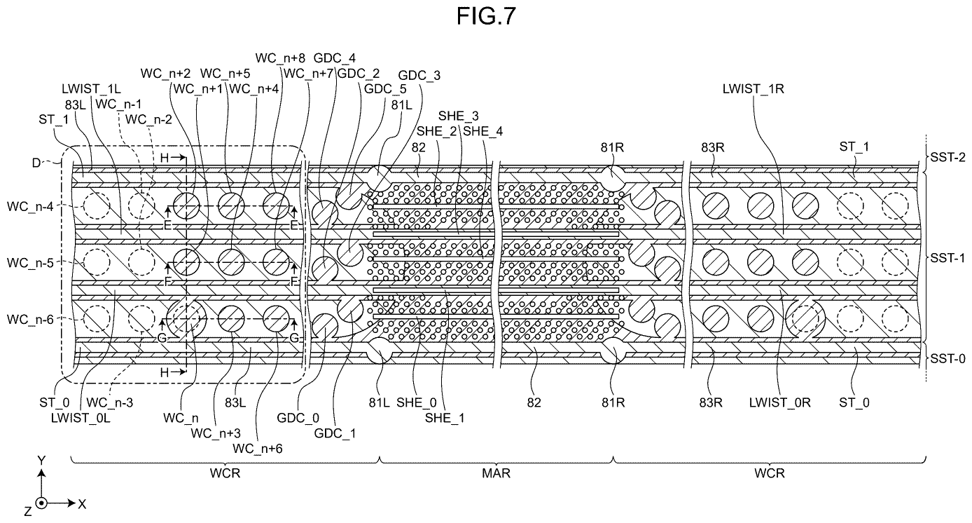

As illustrated in FIGS. 6 and 7, the semiconductor memory device 1 may have a plurality of stacked bodies SST arranged in the Y direction. FIG. 6 is an XZ cross-sectional view illustrating a schematic configuration of the stacked body. FIG. 7 is an XY plan view illustrating a schematic configuration of the stacked bodies SST, and illustrates an XY plane when FIG. 6 is cut along line B-B. In the line B-B, an insulating layer 5 (corresponding to WL_n) is cut at a portion closest to the −X side and a portion closest to the +X side among four portions arranged in the X direction in the XZ cross-sectional view in FIG. 6, and the conductive layer 6 (SGD) is cut at two portions at the center in the X direction. Correspondingly, in FIG. 7, a planar configuration of the insulating layer 5 (corresponding to WL_n) is illustrated in a portion closest to the −X side and a portion closest to the +X side among four portions in the XY plan view, and a planar configuration of the conductive layer 6 (SGD) is illustrated in two portions at the center in the X direction. FIG. 7 illustrates a plurality of stacked bodies SST_0 to SST_2 arranged in the Y direction.

Each of the stacked bodies SST_0 to SST_2 has a substantially rectangular shape with the X direction as a longitudinal direction in the XY plan view. The stacked body SST_1 is divided from the stacked body SST_0 via the slit ST_0 on the −Y side, and is divided from the stacked body SST_0 via the slit ST_1 on the +Y side.

As illustrated in FIG. 7, each of the slit ST_0 and the slit ST_1 extends in a plate shape in the XZ direction. The slit ST_0 and the slit ST_1 extend in the −Z direction from the +Z side of the stacked body SST and reach a Z position between the source line SL and the substrate SUB. The slit ST_0 covers a side surface on the −Y side of the stacked body SST_1 and continuously extends from a −X side end to a +X side end of the side surface on the −Y side. The slit ST_1 covers the side surface on the +Y side of the stacked body SST_1 and continuously extends from the −X side end to the +X side end of the side surface on the +Y side.

As illustrated in FIGS. 6 and 7, each of the stacked bodies SST may include a memory array region MAR around a center in the X direction in the XY plan view, and may include a contact region WCR around both ends in the X direction. The memory cell array 2 is disposed in the memory array region MAR. In the contact region WCR, a stepwise contact plug structure for electrically accessing the memory cell array 2 is arranged. The stepwise contact plug structure is a structure in which a plurality of contact plugs having different depths is arranged stepwise.

The slit ST_0 includes columnar insulators 81L and 81R, an insulating film 82, and insulating films 83L and 83R. In the slit ST_0, the insulating film 82 extends in the XZ direction to cover the side surface on the −Y side of the stacked body SST in the memory array region MAR.

The insulating film 83L extends in the XZ direction and covers the side surface on the −Y side of the stacked body SST with the contact region WCR on the −X side. The columnar insulator 81L extends in the Z direction between the insulating film 83L and the insulating film 82. A side surface of the columnar insulator 81L on the −X side is connected to the insulating film 83L, and a side surface on the +X side is connected to the insulating film 82. A side surface of the columnar insulator 81L on the −X side is in contact with the insulating film 83L, and a side surface on the +X side is in contact with the insulating film 82. The XY plane shape of the columnar insulator 81L is not limited to the substantially circular shape illustrated in FIG. 7, and may be any shape in which the side surface on the −X side is in contact with the insulating film 83L and the side surface on the +X side is in contact with the insulating film 82.

The insulating film 83R extends in the XZ direction and covers the side surface on the −Y side of the stacked body SST with the contact region WCR on the +X side. The columnar insulator 81R extends in the Z direction between the insulating film 82 and the insulating film 83R. A side surface of the columnar insulator 81R on the −X side is connected to the insulating film 82, and a side surface on the +X side is connected to the insulating film 83R. A side surface of the columnar insulator 81R on the −X side is in contact with the insulating film 82, and a side surface on the +X side is in contact with the insulating film 83R. The XY plane shape of the columnar insulator 81R is not limited to the substantially circular shape illustrated in FIG. 7, and may be any shape in which the side surface on the −X side is in contact with the insulating film 82 and the side surface on the +X side is in contact with the insulating film 83R.

The slit ST_1 includes the columnar insulators 81L and 81R, the insulating film 82, and the insulating films 83L and 83R. In the slit ST_1, the insulating film 82 extends in the XZ direction to cover a side surface on the +Y side of the stacked body SST in the memory array region MAR.

The insulating film 83L extends in the XZ direction and covers a side surface on the +Y side of the stacked body SST with the contact region WCR on the −X side. The columnar insulator 81L extends in the Z direction between the insulating film 83L and the insulating film 82. A side surface of the columnar insulator 81L on the −X side is connected to the insulating film 83L, and a side surface on the +X side is connected to the insulating film 82. A side surface of the columnar insulator 81L on the −X side is in contact with the insulating film 83L, and a side surface on the +X side is in contact with the insulating film 82. The XY plane shape of the columnar insulator 81L is not limited to the substantially circular shape exemplified in FIG. 7, and the columnar insulator 81L may have any shape in which the side surface on the −X side is in contact with the insulating film 83L and the side surface on the +X side is in contact with the insulating film 82.

The insulating film 83R extends in the XZ direction and covers the side surface on the +Y side of the stacked body SST with the contact region WCR on the +X side. The columnar insulator 81R extends in the Z direction between the insulating film 82 and the insulating film 83R. A side surface of the columnar insulator 81R on the −X side is connected to the insulating film 82, and a side surface on the +X side is connected to the insulating film 83R. A side surface of the columnar insulator 81R on the −X side is in contact with the insulating film 82, and a side surface on the +X side is in contact with the insulating film 83R. The XY plane shape of the columnar insulator 81R is not limited to the substantially circular shape illustrated in FIG. 7, and the columnar insulator 81R may have any shape in which the side surface on the −X side is in contact with the insulating film 82 and the side surface on the +X side is in contact with the insulating film 83R.

In the memory array region MAR, as mentioned above, the conductive layer 6 and the insulating layer 7 are alternately and repeatedly stacked. In the contact region WCR, the insulating layer 5 and the insulating layer 7 are alternately and repeatedly stacked. Each insulating layer 5 can be formed of a material containing an insulator (e.g., semiconductor nitride such as silicon nitride) as a main component.

A plurality of insulating layers 5 in the contact region WCR correspond to a plurality of conductive layers 6 in the memory array region MAR. The Z position of the insulating layer 5 is substantially equal to the Z position of the corresponding conductive layer 6.

The line B-B illustrated in FIG. 6 passes through the insulating layer 5 corresponding to the conductive layer 6 (word line WL_n) on the −X side and the +X side, and passes through the conductive layer 6 (selection gate line SGD) on a center side in the X direction. The conductive layer 6 (word line WL_n) is the (n+4) th conductive layer 6 from the +Z side. The insulating layer 5 (corresponding to the word line WL_n) is the (n+4) th insulating layer 5 from the +Z side. The word line WL_n indicates the (n+1) th word line WL from the +Z side. n is an arbitrary integer of 2 or more and less than m.

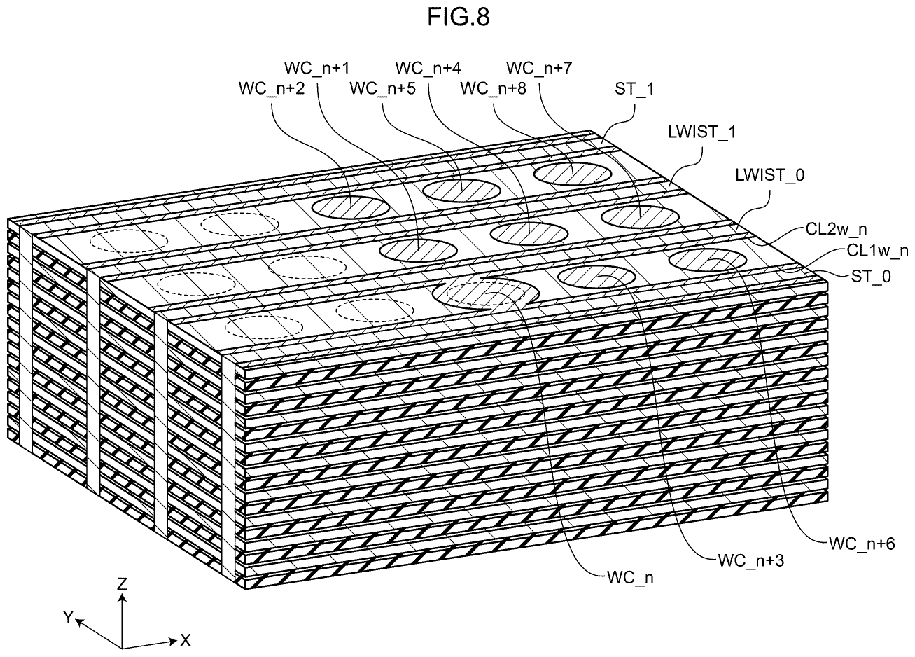

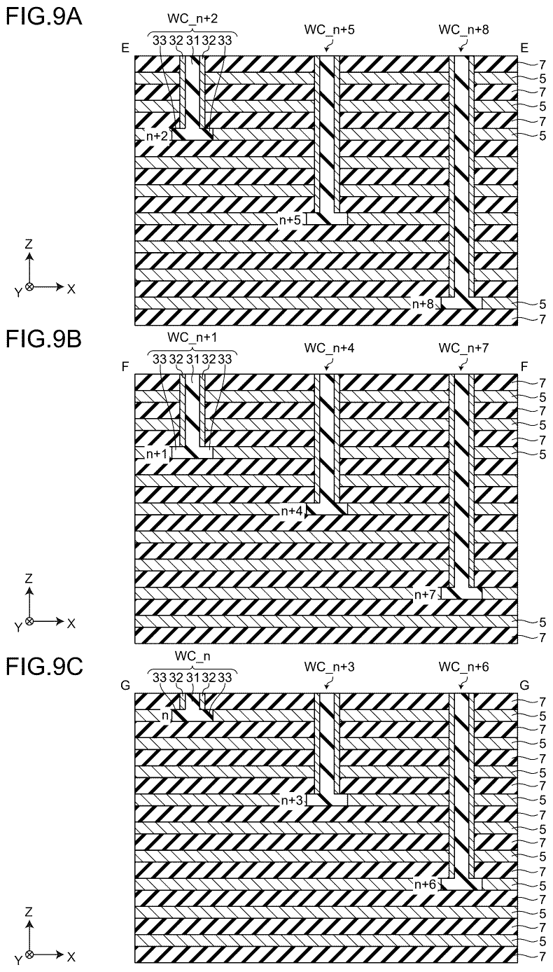

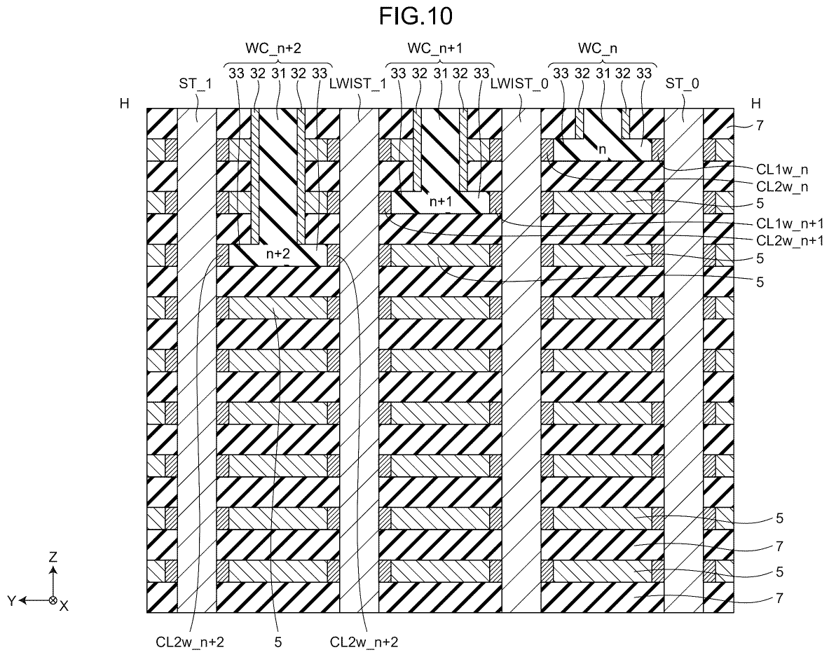

As illustrated in FIGS. 7 to 8, the semiconductor memory device 1 further includes, for each contact region WCR, a contact plug GDC, m contact plugs WC, a contact plug GSC, a contact plug SC, a conductive line CL1gd, a conductive line CL2gd, a conductive line CL1w, a conductive line CL2w, a conductive line CL1w, and a conductive line CL2w. FIG. 8 is a perspective view illustrating a schematic configuration of the contact region WCR on the −X side, and is a perspective view corresponding to a portion D in FIG. 7. The contact plug GDC, m contact plugs WC, the contact plug GSC, and the contact plug SC form a stepwise contact plug structure having different depths stepwise. In the stepwise contact plug structure, the depth of the contact plug only needs to increase stepwise, and is not limited to a structure in which the depth increases in the X direction and the Y direction in a permutation manner (see FIGS. 9A to 9C and 10), and a structure in which the depth increases from both ends in the X direction toward the center or a structure in which the depth increases from both ends in the Y direction toward the center may be used.

In each contact region WCR, m contact plugs WC may be arranged in multiple lines.

The semiconductor memory device 1 further includes one or more insulating films LWIST in each contact region WCR. In FIG. 7, two insulating films LWIST_0L and LWIST_1L are illustrated for the contact region WCR on the −X side, and two insulating films LWIST_0R and LWIST_1R are illustrated for the contact region WCR on the +X side.

Each of the insulating films LWIST extends at least in the Z direction and is distributed in the Y direction in each contact region WCR. Each of the insulating films LWIST may be disposed between the slits ST_0 and ST_1 in the Y direction in each contact region WCR. Each insulating film LWIST may extend in a plate shape in the XZ direction in each contact region WCR. Each insulating film LWIST reaches the Z position between the conductive layer 6 (word line WL) and the conductive layer 6 (source line SL) in each contact region WCR. Each insulating film LWIST may extend from each contact region WCR to an XY position overlapping the insulating film SHE of the memory array region MAR in the XZ direction. As a result, each contact region WCR can be divided into a plurality of regions extending in the XZ direction and aligned in the Y direction. Accordingly, in the contact region WCR, the plurality of insulating layers 5 extending in the XY direction and arranged in the Y direction are arranged, and the contact plugs WC penetrating the respective insulating layers 5 are arranged in the X direction. As a result, the m contact plugs WC in each contact region WCR can be arranged in multiple lines.

In the memory array region MAR, the plurality of conductive layers 6 (selection gate lines SGD) are divided in the Y direction by the plurality of insulating films SHE and the plurality of insulating films LWIST. The insulating films SHE_0 to SHE_4 reach the Z position between the conductive layer 6 (selection gate line SGD) and the conductive layer 6 (word line WL_0) from the +Z side of the stacked body SST. As a result, the memory array region MAR of the stacked body SST is divided into a plurality of string units SU0 to SU5 (see FIG. 3) that can be driven independently of each other. The plurality of string units SU0 to SU5 is aligned in the Y direction and extend in the X direction and the Z direction.

In the example in FIG. 7, five insulating films SHE_0 to SHE_4 are arranged in the memory array region MAR from the −Y side. Each of the insulating films SHE_0 to SHE_4 may extend in a plate shape in the XZ direction in the memory array region MAR. The insulating films SHE_0 to SHE_4 reach the Z position between the conductive layer 6 (selection gate line SGD) and the conductive layer 6 (word line WL_0) from the +Z side of the stacked body SST.

The insulating film LWIST_0L is arranged between the slits ST_0 and ST_1 in the Y direction in the contact region WCR on the −X side. The insulating film LWIST_0L extends in a plate shape in the XZ direction in the contact region WCR on the −X side. The insulating film LWIST_0L reaches the Z position between the insulating layer 5 (corresponding to the word line WL) and the insulating layer 5 (corresponding to the source line SL) from the +Z side of the stacked body SST in the contact region WCR on the −X side. The insulating film LWIST_0L extends from the contact region WCR on the −X side to the XY position overlapping the insulating film SHE_1 of the memory array region MAR in the XZ direction.

The insulating film LWIST_1L is arranged between the slits ST_0 and ST_1 in the Y direction in the contact region WCR on the −X side. The insulating film LWIST_1L is arranged between the insulating film LWIST_0L and the slit ST_1 in the Y direction in the contact region WCR on the −X side. The insulating film LWIST_1L extends in a plate shape in the XZ direction in the contact region WCR on the −X side. The insulating film LWIST_1L reaches the Z position between the insulating layer 5 (corresponding to the word line WL) and the insulating layer 5 (corresponding to the source line SL) from the +Z side of the stacked body SST in the contact region WCR on the −X side. The insulating film LWIST_1L extends from the contact region WCR on the −X side to the XY position overlapping the insulating film SHE_3 of the memory array region MAR in the XZ direction.

In the contact region WCR on the −X side, the insulating films LWIST_0L and LWIST_1L are arranged between the slits ST_0 and ST_1, so that the contact region WCR can be divided into three regions each extending in the XZ direction and aligned in the Y direction as illustrated in FIG. 8. In the contact region WCR, three insulating layers 5 extending in the XY direction and aligned in the Y direction are arranged, and the contact plugs WC penetrating the respective insulating layers 5 are arranged in the X direction. As a result, the m contact plugs WC in the contact region WCR on the −X side can be arranged in three lines.

Similarly, the insulating film LWIST_0R is arranged between the slits ST_0 and ST_1 in the Y direction in the contact region WCR on the +X side. The insulating film LWIST_0R extends in a plate shape in the XZ direction in the contact region WCR on the +X side. The insulating film LWIST_0R reaches the Z position between the insulating layer 5 (corresponding to the word line WL) and the insulating layer 5 (corresponding to the source line SL) from the +Z side of the stacked body SST in the contact region WCR on the +X side. The insulating film LWIST_0R extends from the contact region WCR on the +X side to the XY position overlapping the insulating film SHE_1 of the memory array region MAR in the XZ direction.

The insulating film LWIST_1R is disposed between the slits ST_0 and ST_1 in the Y direction in the contact region WCR on the +X side. The insulating film LWIST_1R is arranged between the insulating film LWIST_0R and the slit ST_1 in the Y direction in the contact region WCR on the +X side. The insulating film LWIST_1R extends in a plate shape in the XZ direction in the contact region WCR on the +X side. The insulating film LWIST_1R reaches the Z position between the insulating layer 5 (corresponding to the word line WL) and the insulating layer 5 (corresponding to the source line SL) from the +Z side of the stacked body SST in the contact region WCR on the +X side. The insulating film LWIST_1R extends from the contact region WCR on the +X side to the XY position overlapping the insulating film SHE_3 of the memory array region MAR in the XZ direction.

In the contact region WCR on the +X side, the insulating films LWIST_0R and LWIST_1R are arranged between the slits ST_0 and ST_1, so that the contact region WCR can be divided into three regions each extending in the XZ direction and aligned in the Y direction (see FIG. 8). In the contact region WCR, three insulating layers 5 extending in the XY direction and aligned in the Y direction are arranged, and the contact plugs WC penetrating the respective insulating layers 5 are arranged in the X direction. As a result, the m contact plugs WC in the contact region WCR on the +X side can be arranged in three lines.

The contact plug GDC corresponds to the conductive layer 6 (selection gate line SGD), and is disposed at a position on the +X side in the contact region WCR on the −X side and at a position on the −X side in the contact region WCR on the +X side. The contact plug GDC extends through the contact region WCR in the −Z direction from the +Z side of the contact region WCR. The contact plug GDC reaches the Z position of the insulating layer 5 corresponding to the conductive layer 6 (selection gate line SGD).

A plurality of contact plugs GDC can be provided in accordance with division of the selection gate line SGD in the Y direction by the insulating film SHE. In FIG. 7, six contact plugs GDC_0 to GDC_5 are provided by division of the selection gate line SGD into six in the Y direction by five insulating films SHE.

The conductive line CL1gd corresponds to the conductive layer 6 (selection gate line SGD) and corresponds to the insulating layer 5 corresponding to the conductive layer 6 (selection gate line SGD). The conductive line CL1gd is disposed between the insulating layer 5 corresponding to the conductive layer 6 (selection gate line SGD) and the slit ST_0 or the insulating films LWIST_0 and LWIST_1. The conductive line CL1gd extends in the X direction along the side surface on the −Y side of the insulating layer 5 corresponding to the conductive layer 6 (selection gate line SGD). The conductive line CL1gd may be formed of a material containing a conductive material (e.g., metal such as tungsten) as a main component.

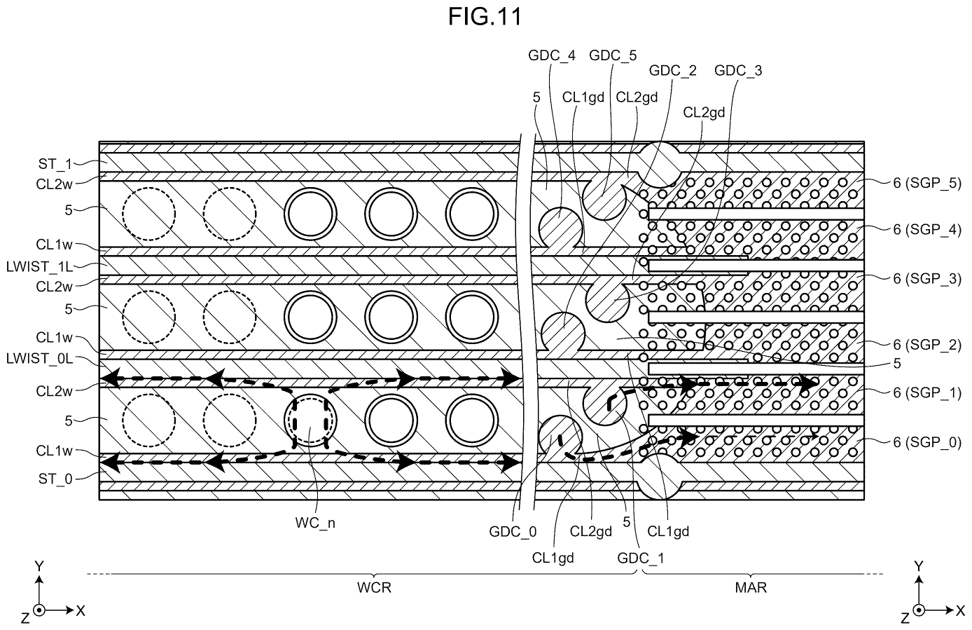

The conductive line CL1gd corresponds to even-numbered contact plugs GDC0, GDC2, and GDC4 among the plurality of contact plugs GDC_0 to GDC_5. The conductive line CL1gd is connected to the side surface of the corresponding contact plug GDC exposed on the −Y side surface of the corresponding insulating layer 5 in the contact region WCR (see FIG. 11).

The conductive line CL1gd is connected to a −X-side end of the corresponding conductive layer 6 (selection gate line SGD) at a boundary between the contact region WCR on the −X-side and the memory array region MAR. The conductive line CL1gd is connected to a +X-side end of the corresponding conductive layer 6 (selection gate line SGD) at a boundary between the contact region WCR on the +X-side and the memory array region MAR.

The conductive line CL2gd corresponds to the conductive layer 6 (selection gate line SGD) and corresponds to the insulating layer 5 corresponding to the conductive layer 6 (selection gate line SGD). The conductive line CL2gd is disposed between the insulating layer 5 corresponding to the conductive layer 6 (selection gate line SGD) and the slit ST_1 or the insulating films LWIST_0 and LWIST_1. The conductive line CL2gd extends in the X direction along the side surface on the +Y side of the insulating layer 5 corresponding to the conductive layer 6 (selection gate line SGD). The conductive line CL2gd may be formed of a material containing a conductive material (e.g., metal such as tungsten) as a main component.

The conductive line CL2gd corresponds to odd-numbered contact plugs GDC1, GDC3, and GDC5 among the plurality of contact plugs GDC_0 to GDC_5. The conductive line CL2gd is connected to the side surface of the corresponding contact plug GDC exposed on the +Y side surface of the corresponding insulating layer 5 in the contact region WCR (see FIG. 11).

The conductive line CL2gd is connected to the −X-side end of the corresponding conductive layer 6 (selection gate line SGD) at the boundary between the contact region WCR on the −X-side and the memory array region MAR. The conductive line CL2gd is connected to the +X-side end of the corresponding conductive layer 6 (selection gate line SGD) at the boundary between the contact region WCR on the +X-side and the memory array region MAR.

The m contact plugs WC correspond to the m conductive layers 6 (the m word lines WL_0 to WL_m−1). The contact plug WC extends in the −Z direction from the +Z side of the stacked body SST and reaches the Z position of the insulating layer 5 corresponding to the corresponding conductive layer 6 (word line WL) in the stacked body SST.

The contact plug WC is connected to the conduct lines CL on each side surface of both side of the contact plug WC in the Y direction.

The conductive line CL1w corresponds to the contact plug WC. The conductive line CL1w is connected to the side surface of the contact plug WC exposed on the side surface on the −Y side of the corresponding insulating layer 5 in the contact region WCR.

The conductive line CL1w is connected to the −X-side end of the corresponding conductive layer 6 (word line WL) at the boundary between the contact region WCR on the −X side and the memory array region MAR. The conductive line CL1w is connected to the +X-side end of the corresponding conductive layer 6 (word line WL) at the boundary between the +X-side contact region WCR and the memory array region MAR.

The conductive line CL2w corresponds to the conductive layer 6 (word line WL) and corresponds to the insulating layer 5 corresponding to the conductive layer 6 (word line WL). The conductive line CL2w is disposed between the insulating layer 5 corresponding to the conductive layer 6 (word line WL) and the slit ST_1 or the insulating films LWIST_0 and LWIST_1. The conductive line CL2w extends in the X direction along the side surface on the +Y side of the insulating layer 5 corresponding to the conductive layer 6 (word line WL).

The conductive line CL2w corresponds to the contact plug WC. The conductive line CL2w is connected to the side surface of the contact plug WC exposed on the surface on the +Y side of the corresponding insulating layer 5 in the contact region WCR.

The conductive line CL2w is connected to the −X-side end of the corresponding conductive layer 6 (word line WL) at the boundary between the contact region WCR on the −X side and the memory array region MAR. The conductive line CL2w is connected to the +X-side end of the corresponding conductive layer 6 (word line WL) at the boundary between the +X-side contact region WCR and the memory array region MAR.

Although not illustrated, the contact plug GSC corresponds to the conductive layer 6 (selection gate line SGS) and is disposed in the contact region WCR on the −X side and the contact region WCR on the +X side. The contact plug GDC extends through the contact region WCR in the −Z direction from the +Z side of the contact region WCR. The contact plug GSC reaches the Z position of the insulating layer 5 corresponding to the conductive layer 6 (selection gate line SGS).

The conductive line CL1gs corresponds to the conductive layer 6 (selection gate line SGS) and corresponds to the insulating layer 5 corresponding to the conductive layer 6 (selection gate line SGS). The conductive line CL1gs is disposed between the insulating layer 5 corresponding to the conductive layer 6 (selection gate line SGS) and the slit ST_0 or the insulating films LWIST_0 and LWIST_1. The conductive line CL1gs extends in the X direction along the side surface on the −Y side of the insulating layer 5 corresponding to the conductive layer 6 (selection gate line SGS). The conductive line CL1gs may be made of a material containing a conductive material (e.g., metal such as tungsten) as a main component.

The conductive line CL1gs corresponds to the contact plug GSC. The conductive line CL1gs is connected to the side surface of the contact plug GSC exposed on the surface on the −Y side of the corresponding insulating layer 5 in the contact region WCR.

The conductive line CL1gs is connected to the −X-side end of the corresponding conductive layer 6 (selection gate line SGS) at the boundary between the −X-side contact region WCR and the memory array region MAR. The conductive line CL1gs is connected to the +X-side end of the corresponding conductive layer 6 (selection gate line SGS) at the boundary between the +X-side contact region WCR and the memory array region MAR.

The conductive line CL2gs corresponds to the conductive layer 6 (selection gate line SGS) and corresponds to the insulating layer 5 corresponding to the conductive layer 6 (selection gate line SGS). The conductive line CL2gs is disposed between the insulating layer 5 corresponding to the conductive layer 6 (selection gate line SGS) and the slit ST_1 or the insulating films LWIST_0 and LWIST_1. The conductive line CL2gs extends in the X direction along the side surface on the +Y-side of the insulating layer 5 corresponding to the conductive layer 6 (selection gate line SGS). The conductive line CL2gs may be made of a material containing a conductive material (e.g., metal such as tungsten) as a main component.

The conductive line CL2gs corresponds to the contact plug GSC. The conductive line CL2gs is connected to the side surface of the corresponding contact plug GSC exposed on the surface on the +Y side of the corresponding insulating layer 5 in the contact region WCR.

The conductive line CL2gs is connected to the −X-side end of the corresponding conductive layer 6 (selection gate line SGS) at the boundary between the −X-side contact region WCR and the memory array region MAR. The conductive line CL2gs is connected to the +X-side end of the corresponding conductive layer 6 (selection gate line SGS) at the boundary between the +X-side contact region WCR and the memory array region MAR.

Although not illustrated, the contact plug SC corresponds to the conductive layer 6 (source line SL) and is disposed at a position on the −X side in the contact region WCR on the −X side and a position on the −X side in the contact region WCR on the +X side. The contact plug SC extends in the −Z direction from the +Z side of the stacked body SST and reaches the Z position of the insulating layer 5 corresponding to the conductive layer 6 (source line SL) in the stacked body SST.

In each contact region WCR, the insulating layer 5 is disposed at the Z position corresponding to the conductive layer 6 of the memory array region MAR, so that the plurality of insulating layers 7 separated from each other in the Z direction can be structurally reinforced.

For example, at the time of manufacturing, a stacked body SSTa in which the insulating layer 5 and the insulating layer 7 are alternately stacked a plurality of times is formed, and a contact processing process of making a large number of stages with a small number of processing times is applied, whereby a stepwise contact plug structure is formed in the contact region WCR. In other words, a plurality of contact plugs having different depths are formed in the contact region WCR in a stepwise manner. In an etching process, the conductive layer 6 is formed by removing the insulating layer 5 in the memory array region MAR, forming a gap in the plurality of insulating layers 7, and embedding a conductive material in the gap.

In a period from formation of the gap to formation of the conductive layer 6, the insulating layer 5 is removed as a sacrificial layer in the memory array region MAR, but in the contact region WCR, the insulating layer 5 remains between the plurality of insulating layers 7 and supports between the plurality of insulating layers 7. In the stacked body SSTa, the insulating layers 5 remaining in the contact region WCR can structurally reinforce the plurality of insulating layers 7 separated from each other in the Z direction.

In other words, with this structure, the plurality of insulating layers 7 separated from each other in the Z direction in the contact region WCR can be structurally reinforced without additionally providing an insulating film HR serving as a reinforcing material. As a result, it is possible to avoid a defect caused by additionally providing the insulating film HR serving as the reinforcing material.

In each contact region WCR, the contact plug WC can be configured as illustrated in FIGS. 7 to 10. FIGS. 9A to 9C are XZ cross-sectional views illustrating a configuration of the contact region WCR. FIG. 9A illustrates an XZ cross section taken along line E-E in FIG. 7. FIG. 9B illustrates an XZ cross section taken along line F-F in FIG. 7. FIG. 9C illustrates an XZ cross section taken along line G-G in FIG. 7. FIG. 10 is a YZ sectional view illustrating a configuration of the contact region WCR, and is a YZ cross section taken along line H-H in FIG. 7.

For example, the contact plug WC_n illustrated in FIGS. 9C and 10 includes a columnar portion 31, a cylindrical portion 32, and a plate-like portion 33. The contact plug WC_n corresponds to the conductive layer 6 (word line WL_n).

The columnar portion 31 extends in the −Z direction from the +Z side of the stacked body SST and is in contact with a +Z-side surface of the plate-like portion 33. The columnar portion 31 may have a substantially columnar shape. The columnar portion 31 may be formed of a material containing a conductive material (e.g., metal such as tungsten) as a main component.

The cylindrical portion 32 covers the side surface of the columnar portion 31 from the outside in the XY direction. The cylindrical portion 32 may have a substantially cylindrical shape. The cylindrical portion 32 can be formed of a material containing an insulator (e.g., semiconductor oxide such as silicon oxide) as a main component. As a result, the cylindrical portion 32 insulates the columnar portion 31 from the film or layer on the outer side in the XY direction.

The plate-like portion 33 extends in a plate shape in the XY direction. The plate-like portion 33 may have a substantially circular plate shape. The maximum X width of the plate-like portion 33 is larger than the maximum X width of the columnar portion 31. The maximum Y width of the plate-like portion 33 is larger than the maximum Y width of the columnar portion 31. The plate-like portion 33 includes the columnar portion 31 inside when viewed from the Z direction. The plate-like portion 33 may be formed of a material containing a conductive material (e.g., metal such as tungsten) as a main component.

The plate-like portion 33 is disposed at the Z position of the conductive layer 6 corresponding to the contact plug WC. The plate-like portion 33 of the contact plug WC_n is disposed at the Z position corresponding to the conductive layer 6 (word line WL_n). The plate-like portion 33 is disposed between the insulating film LWIST_0 and the slit ST_0 in the Y direction.

The side surface of the plate-like portion 33 on the −Y side faces the slit SL_0 via the conductive line CL1w_n. The side surface on the −Y side of the plate-like portion 33 is in contact with the conductive line CL1w_n. The conductive line CL1w_n corresponds to the conductive layer 6 (word line WL_n). The conductive line CL1w_n extends in the X direction and is connected to the conductive layer 6 (word line WL_n).

The side surface on the +Y side of the plate-like portion 33 faces the insulating film LWIST_0 via the conductive line CL2w_n. The side surface on the +Y side of the plate-like portion 33 is in contact with the conductive line CL2w_n. The conductive line CL2w_n corresponds to the conductive layer 6 (word line WL_n). The conductive line CL2w_n extends in the X direction and is connected to the conductive layer 6 (word line WL_n).

As a result, a signal transmitted from the columnar portion 31 of the contact plug WC_n of the contact region WCR to the plate-like portion 33 is transmitted from both side surfaces of the plate-like portion 33 in the Y direction to the conductive layer 6 (word line WL_n) of the memory cell array region MAR through the two conductive lines CL1w_n and CL2w_n as indicated by dotted arrows in FIG. 11. FIG. 11 is a plan view illustrating signal transmission from the contact region WCR to the memory cell array region MAR. In other words, since this signal transmission configuration uses two parallel routes, a signal transmission speed can be easily increased.

Similarly, a contact plug WC_n+1 illustrated in FIGS. 9B and 10 includes the columnar portion 31, the cylindrical portion 32, and the plate-like portion 33. The contact plug WC_n+1 corresponds to the conductive layer 6 (word line WL_n+1).

Specific configurations of the columnar portion 31, the cylindrical portion 32, and the plate-like portion 33 are similar to those of the contact plug WC_n except for the following points.

The plate-like portion 33 of the contact plug WC_n+1 is disposed at the Z position corresponding to the conductive layer 6 (word line WL_n+1).

The side surface on the −Y side of the plate-like portion 33 faces the slit SL_0 via a conductive line CL1w_n+1. The side surface on the −Y side of the plate-like portion 33 is in contact with the conductive line CL1w_n+1. The conductive line CL1w_n+1 corresponds to the conductive layer 6 (word line WL_n+1). The conductive line CL1w_n+1 extends in the X direction and is connected to the conductive layer 6 (word line WL_n+1).

The side surface on the +Y side of the plate-like portion 33 faces the insulating film LWIST_0 via the conductive line CL2w_n+1. The conductive line CL2w_n+1 corresponds to the conductive layer 6 (word line WL_n+1). The conductive line CL2w_n+1 extends in the X direction and is connected to the conductive layer 6 (word line WL_n+1).

A contact plug WC_n+2 illustrated in FIGS. 9A and 10 includes the columnar portion 31, the cylindrical portion 32, and the plate-like portion 33. The contact plug WC_n+2 corresponds to the conductive layer 6 (word line WL_n+2).

Specific configurations of the columnar portion 31, the cylindrical portion 32, and the plate-like portion 33 are similar to those of the contact plug WC_n except for the following points.

The plate-like portion 33 of the contact plug WC_n+2 is disposed at the Z position corresponding to the conductive layer 6 (word line WL_n+2).

The side surface on the −Y side of the plate-like portion 33 faces the slit SL_0 via the conductive line CL1w_n+2. The side surface on the −Y side of the plate-like portion 33 is in contact with the conductive line CL1w_n+2. The conductive line CL1w_n+2 corresponds to the conductive layer 6 (word line WL_n+2). The conductive line CL1w_n+2 extends in the X direction and is connected to the conductive layer 6 (word line WL_n+2).

The side surface on the +Y side of the plate-like portion 33 faces the insulating film LWIST_0 via the conductive line CL2w_n+2. The side surface on the +Y side of the plate-like portion 33 is in contact with the conductive line CL2w_n+2. The conductive line CL2w_n+2 corresponds to the conductive layer 6 (word line WL_n+2). The conductive line CL2w_n+2 extends in the X direction and is connected to the conductive layer 6 (word line WL_n+2).

Configurations of the other contact plugs WC (e.g., WC_n+3 to WC_n+8) are similar to the configurations of the contact plugs WC_n to WC_n+2. Although not illustrated, a configuration of the contact plug GSC is similar to the configurations of the contact plugs WC_n to WC_n+2.

A configuration of the contact plug GDC is basically similar to the configurations of the contact plugs WC_n to WC_n+2, but differs in the following points.

In the plate-like portion 33 of the contact plug GDC_0, the side surface on the −Y side faces the slit SL_0 via the conductive line CL1gd, and the side surface on the +Y side faces the insulating film LWIST_0 via the insulating layer 5 (see FIGS. 7 and 11). The side surface on the −Y side of the plate-like portion 33 is in contact with the conductive line CL1gd, and the side surface on the +Y side is separated from the conductive line CL2gd via the insulating layer 5. The conductive line CL1gd extends in the X direction and is connected to the conductive layer 6 (selection gate line SGD_0). As a result, the contact plug GDC_0 is connected to the conductive layer 6 (selection gate line SGD_0) via the conductive line CL1gd.

In the plate-like portion 33 of the contact plug GDC_1, the side surface on the −Y side faces the slit SL_0 via the insulating layer 5, and the side surface on the +Y side faces the insulating film LWIST_0 via the conductive line CL2gd (see FIGS. 7 and 11). In the plate-like portion 33, the side surface on the −Y side is separated from the conductive line CL1gd via the insulating layer 5, and the side surface on the +Y side is in contact with the conductive line CL2gd. The conductive line CL2gd extends in the X direction and is connected to the conductive layer 6 (selection gate line SGD_1). As a result, the contact plug GDC_1 is connected to the conductive layer 6 (selection gate line SGD_1) via the conductive line CL2gd.

In the plate-like portion 33 of the contact plug GDC_2, the side surface on the −Y side faces the insulating film LWIST_0 via the conductive line CL1gd, and the side surface on the +Y side faces the insulating film LWIST_1 via the insulating layer 5 (see FIGS. 7 and 11). The side surface on the −Y side of the plate-like portion 33 is in contact with the conductive line CL1gd, and the side surface on the +Y side is separated from the conductive line CL2gd via the insulating layer 5. The conductive line CL1gd extends in the X direction and is connected to the conductive layer 6 (selection gate line SGD_2). As a result, the contact plug GDC_2 is connected to the conductive layer 6 (selection gate line SGD_2) via the conductive line CL1gd.

In the plate-like portion 33 of the contact plug GDC_3, the side surface on the −Y side faces the insulating film LWIST_0 via the insulating layer 5, and the side surface on the +Y side faces the insulating film LWIST_1 via the conductive line CL2gd (see FIGS. 7 and 11). In the plate-like portion 33, the side surface on the −Y side is separated from the conductive line CL1gd via the insulating layer 5, and the side surface on the +Y side is in contact with the conductive line CL2gd. The conductive line CL2gd extends in the X direction and is connected to the conductive layer 6 (selection gate line SGD_3). As a result, the contact plug GDC_3 is connected to the conductive layer 6 (selection gate line SGD_3) via the conductive line CL2gd.

In the plate-like portion 33 of a contact plug GDC_4, the side surface on the −Y side faces the insulating film LWIST_1 via the conductive line CL1gd, and the side surface on the +Y side faces the slit SL_1 via the insulating layer 5 (see FIGS. 7 and 11). The side surface on the −Y side of the plate-like portion 33 is in contact with the conductive line CL1gd, and the side surface on the +Y side is separated from the conductive line CL2gd via the insulating layer 5. The conductive line CL1gd extends in the X direction and is connected to the conductive layer 6 (selection gate line SGD_4). As a result, the contact plug GDC_4 is connected to the conductive layer 6 (selection gate line SGD_4) via the conductive line CL1gd.

The plate-like portion 33 of the contact plug GDC_5 has a side surface on the −Y side facing the insulating film LWIST_1 via the insulating layer 5, and a side surface on the +Y side facing the slit SL_1 via the conductive line CL2gd (see FIGS. 7 and 11). In the plate-like portion 33, the side surface on the −Y side is separated from the conductive line CL1gd via the insulating layer 5, and the side surface on the +Y side is in contact with the conductive line CL2gd. The conductive line CL2gd extends in the X direction and is connected to the conductive layer 6 (selection gate line SGD_5). As a result, the contact plug GDC_5 is connected to the conductive layer 6 (selection gate line SGD_5) via the conductive line CL2gd.

Unlike other contact plugs WC, GSC, and SC, the contact plugs GDC are in contact with the conductive line CL1gd or CL2gd on one side surface of the plate-like portion 33 in the Y direction. As a result, the signal transmitted from the columnar portions 31 of the contact plugs GDC in the contact region WCR to the plate-like portions 33 is transmitted from the side surface on one side in the Y direction of the plate-like portion 33 to the conductive layer 6 (selection gate line SGD) of the memory cell array region MAR through one conductive line CL1gd or CL2gd as indicated by the dotted arrows in FIG. 11.

A path from the contact plug GDC_0 to the selection gate line SGD_0, a path from the contact plug GDC_1 to the selection gate line SGD_1, a path from the contact plug GDC_2 to the selection gate line SGD_2, a path from the contact plug GDC_3 to the selection gate line SGD_3, a path from the contact plug GDC_4 to the selection gate line SGD_4, and a path from the contact plug GDC_5 to the selection gate line SGD_5 are electrically separated from each other via the insulating layer 5, the insulating film LWIST, and the insulating film SHE. As a result, the selection gate lines SGD_0 to GDC_5 can be controlled independently from each other via the contact plugs GDC_0 to GDC_5.

As described above, in the embodiment, in each contact region WCR of the stacked body SST of the semiconductor memory device 1, the insulating layer 5 and the insulating layer 7 are alternately stacked, and the plurality of contact plugs WC reach the Z position of the corresponding insulating layer 5. At the Z position, both side surfaces of the plurality of contact plugs WC are connected to two conductive lines CL1w and CL2w extending in the X direction along both side surfaces of the insulating layer 5. The plurality of contact plugs WC is connected to the conductive layer 6 in the memory array region MAR via two conductive lines CL1w and CL2w. As a result, it is possible to structurally reinforce the plurality of insulating layers 7 in each contact region WCR while securing a signal transmission path from each contact region WCR to the memory array region MAR. In other words, in the stacked body SST, the plurality of insulating layers 7 separated from each other in the Z direction can be structurally reinforced without additionally providing the insulating film HR as the reinforcing material. Therefore, it is possible to provide the semiconductor memory device 1 suitable for easily processing the contact plug.

For example, at the time of manufacturing, the stacked body SST in which the insulating layer 5 and the insulating layer 7 are alternately stacked a plurality of times is formed, and a contact processing process of making a large number of stages with a small number of processing times is applied, whereby a stepwise contact plug structure is formed in the contact region WCR. Thereafter, the insulating layer 5 is removed as a sacrificial layer in the memory array region MAR, but in the contact region WCR, the insulating layer 5 remains between the plurality of insulating layers 7 and supports between the plurality of insulating layers 7. In the stacked body SST, with this structure, the plurality of insulating layers 7 separated from each other in the Z direction can be structurally reinforced without additionally providing the insulating film HR as the reinforcing material. As a result, it is possible to avoid a defect caused by additionally providing the insulating film HR serving as the reinforcing material.

In other words, since the step of additionally processing the insulating film HR serving as the reinforcing material becomes unnecessary, the manufacturing cost of the semiconductor memory device 1 can be easily reduced.

Still more, since a space for disposing the insulating film HR serving as the reinforcing material becomes unnecessary, restrictions on processing dimensions and layout of the contact plug can be alleviated, and a degree of freedom in designing the contact plug can be improved. Also from this aspect, the manufacturing cost of the semiconductor memory device 1 can be easily reduced.

Further, since a space for disposing the insulating film HR serving as the reinforcing material becomes unnecessary, process restrictions at the time of processing the contact plug can be alleviated, and a degree of difficulty in manufacturing the contact plug can be reduced. Also from this aspect, the manufacturing cost of the semiconductor memory device 1 can be easily reduced.

Note that the shape of the slit ST is not limited to the plate shape, and may be any shape capable of electrically separating the stacked body SST from other stacked bodies SST. For example, the slit ST may have a shape in which a plurality of columnar insulators extending in the Z direction are connected in the X direction and arranged.

The shape of the insulating film LWIST is not limited to the plate shape, and may be any shape suitable for forming the conductive line CL1gd, the conductive line CL2gd, the conductive line CL1w, the conductive line CL2w, the conductive line CL1w, and the conductive line CL2w. For example, the insulating film LWIST may have a shape in which a plurality of columnar insulators extending in the Z direction is connected in the X direction and arranged, or may have a shape in which a plurality of columnar insulators extending in the Z direction is arranged at intervals in the X direction.

Alternatively, although not illustrated, each stacked body SST may include the contact region WCR on one side in the X direction. Each stacked body SST may include the memory array region MAR on one side in the X direction in the XY planar view, and may include the contact region WCR on the other side in the X direction. The contact region WCR is similar to the embodiment in that the stepwise contact plug structure for electrically accessing the memory cell array 2 is disposed in the contact region WCR.

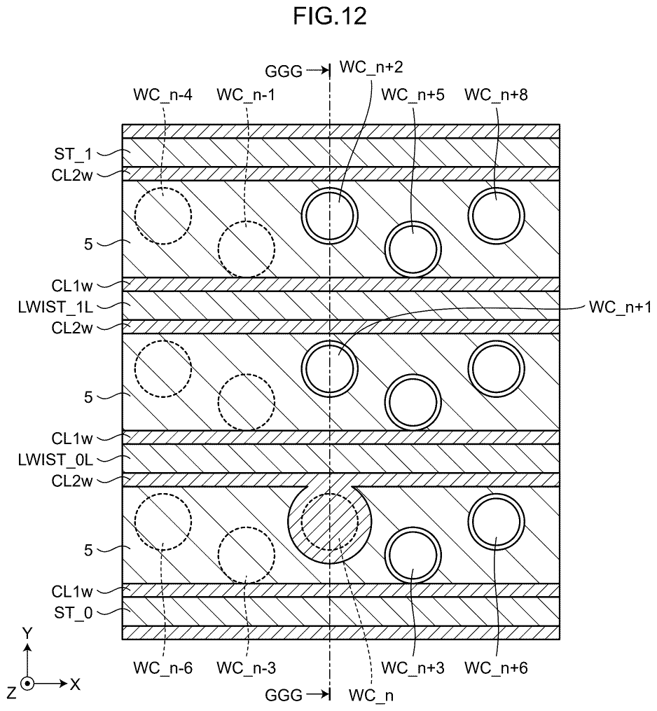

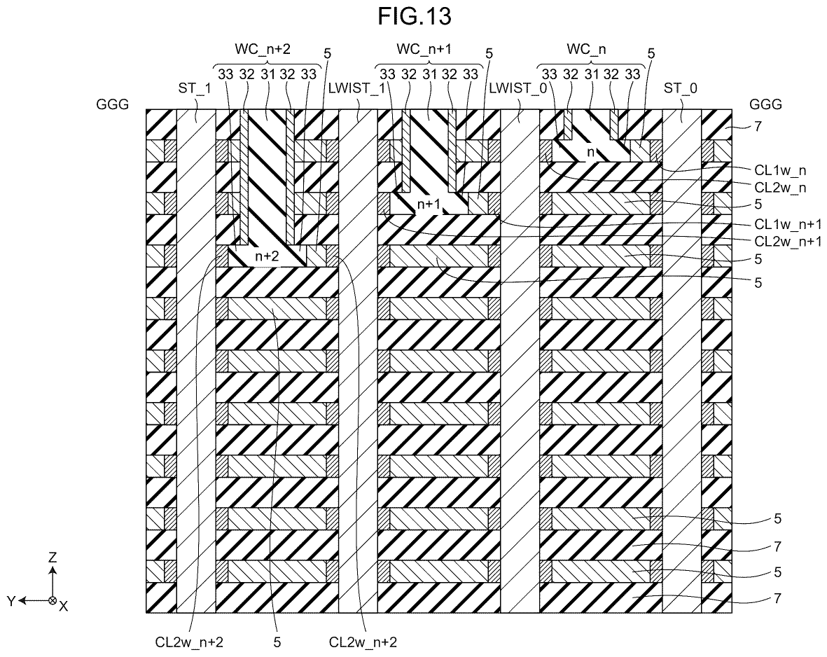

Alternatively, as a first modification of the embodiment, the contact plug WC as illustrated in FIGS. 12 and 13 may be arranged in a staggered manner. FIG. 12 is a plan view illustrating a configuration of the contact region WCR in the first modification of the embodiment. FIG. 13 is a cross-sectional view illustrating a configuration of the contact region WCR in the first modification of the embodiment. FIG. 13 illustrates an XZ cross section taken along line GGG-GGG in FIG. 12.

The contact plugs WC aligned in X direction may be alternately connected to conductive lines CL on +Y-side side surface and on −Y-side side surface.

The conductive line CL1w corresponds to the conductive layer 6 (word line WL) and corresponds to the insulating layer 5 corresponding to the conductive layer 6 (word line WL). The conductive line CL1w is disposed between the insulating layer 5 corresponding to the conductive layer 6 (word line WL) and the slit ST_1 or the insulating films LWIST_0 and LWIST_1. The conductive line CL1w extends in the X direction along the side surface on the −Y side of the insulating layer 5 corresponding to the conductive layer 6 (word line WL).

The conductive line CL1w corresponds to the contact plug WC_n−3 to WC_n−1, WC_n+3 to WC_n+5. The conductive line CL1w is connected to the side surface of the contact plug WC_n−3 to WC_n−1, WC_n+3 to WC_n+5 exposed on the side surface on the −Y side of the corresponding insulating layer 5 in the contact region WCR.

The conductive line CL1w is connected to the −X-side end of the corresponding conductive layer 6 (word line WL) at the boundary between the contact region WCR on the −X side and the memory array region MAR. The conductive line CL1w is connected to the +X-side end of the corresponding conductive layer 6 (word line WL) at the boundary between the +X-side contact region WCR and the memory array region MAR.

The conductive line CL2w corresponds to the conductive layer 6 (word line WL) and corresponds to the insulating layer 5 corresponding to the conductive layer 6 (word line WL). The conductive line CL2w is disposed between the insulating layer 5 corresponding to the conductive layer 6 (word line WL) and the slit ST_1 or the insulating films LWIST_0 and LWIST_1. The conductive line CL2w extends in the X direction along the side surface on the +Y side of the insulating layer 5 corresponding to the conductive layer 6 (word line WL).

The conductive line CL2w corresponds to the contact plug WC_n−6 to WC_n−4, WC_n to WC_n+2, WC_n+6 to WC_n+8. The conductive line CL2w is connected to the side surface of the contact plug WC exposed on the surface on the +Y side of the corresponding insulating layer 5 in the contact region WCR.

The conductive line CL2w is connected to the −X-side end of the corresponding conductive layer 6 (word line WL) at the boundary between the contact region WCR on the −X side and the memory array region MAR. The conductive line CL2w is connected to the +X-side end of the corresponding conductive layer 6 (word line WL) at the boundary between the +X-side contact region WCR and the memory array region MAR.

In this way, a staggered-manner-arrangement of the contact plugs WC may easily reduces the layout area of the contact plugs WC in comparison to that of a straight-line-arrangement.

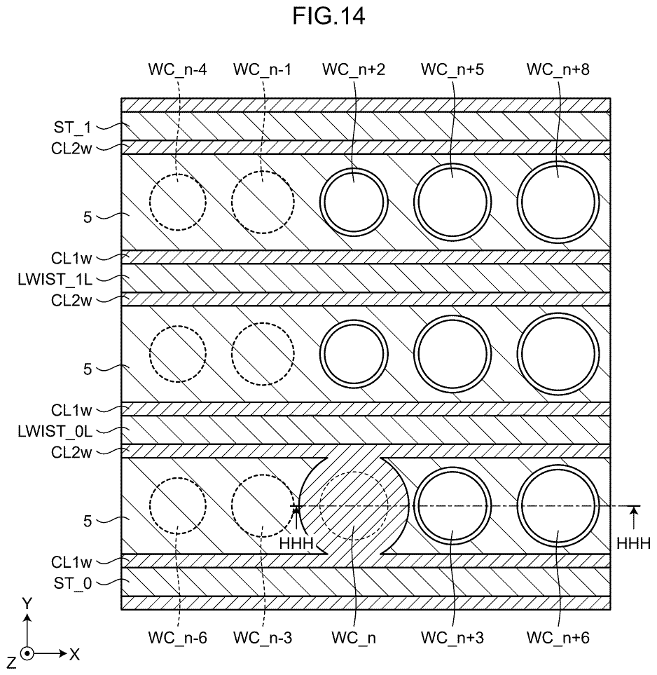

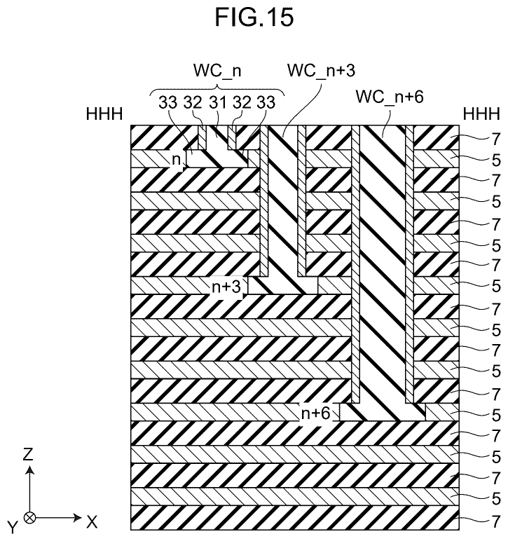

Alternatively, as a second modification of the embodiment, the contact plug WC as illustrated in FIGS. 14 and 15 may be arranged while changing its shape in a gradation manner. FIG. 14 is a plan view illustrating a configuration of the contact region WCR in the second modification of the embodiment. FIG. 15 is a cross-sectional view illustrating a configuration of the contact region WCR in the second modification of the embodiment. FIG. 15 illustrates an XZ cross section taken along line HHH-HHH in FIG. 14.

In FIGS. 14 and 15, a configuration where a diameter and a pitch of the contact plugs WC aligned in the X direction changes in a gradation manner is exemplified. The contact plugs WC aligned in the X direction may increase its diameter and pitch as its contact depth become larger.

For example, the contact plugs WCn−6, WCn−3, WCn, WCn+3, WCn+6 have in this order larger diameters of columnar portion 31. This make it possible to suppress the increase of contact resistance by the increase of contact depth.

The contact plugs WCn−6, WCn−3, WCn, WCn+3, WCn+6 may have equivalent diameter of plate-like portion 33. This make it possible to ensure that the side surface of plate-like portion 33 connected to conductive line CL.

The pitch between contact plugs WCn−6 and WCn−3, the pitch between contact plugs WCn−3 and WCn, the pitch between contact plugs WCn and WCn+3, the pitch between contact plugs WCn+3 and WCn+6 are large in this order. This make it possible to suppress the leakage between contact plugs adjacent in X direction when the diameter is larger depending on the deeper contact depth.

It should be noted that contact plugs aligned in Y direction may have equivalent diameter and pitch.

In this way, gradual increase of diameter and pitch of contact plugs WC aligned in X direction depending on the deeper contact depth allow to suppress the increase of contact resistance and to suppress the leakage between contact plugs adjacent to each other.

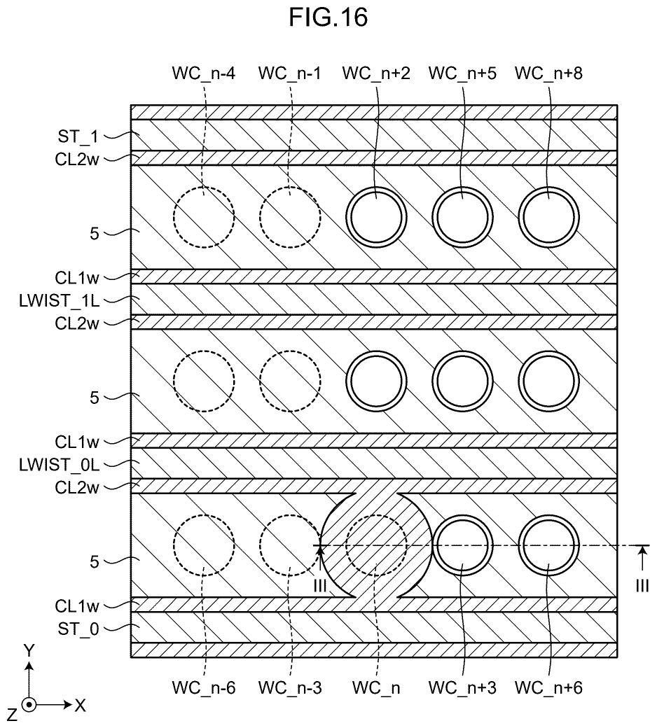

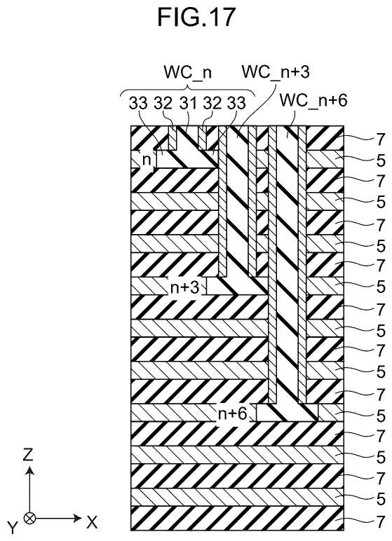

Alternatively, as a third modification of the embodiment, the plate-like portions 33 of contact plugs WC as illustrated in FIGS. 16 and 17 may overlap with each other when transparently viewing from Z direction. FIG. 16 is a plan view illustrating a configuration of the contact region WCR in the third modification of the embodiment. FIG. 17 is a cross-sectional view illustrating a configuration of the contact region WCR in the third modification of the embodiment. FIG. 17 illustrates an XZ cross section taken along line III-III in FIG. 16.

In FIGS. 16 and 17, a configuration where plate-like portion 33 of each contact plug WC overlaps with plate-like portion 33 of contact plug WC adjacent it in X direction when transparently viewing from Z direction is exemplified. The plate-like portion 33 of each contact plug WC may contact cylindrical portion 32 of contact plug WC adjacent to it in X direction.

When transparently viewing from Z direction, plate-like portion 33 of contact plug WCn−3 overlaps with plate-like portion 33 of contact plug WCn−6, WCn. −X-side side surface of contact plug WCn−3 contacts cylindrical portion 32 of contact plug WCn−6 and +X-side side surface of contact plug WCn-3 contacts cylindrical portion 32 of contact plug WCn. This make it possible to easily decrease arrangement pitch in X direction between contact plugs WCn−6, WCn−3, WCn.

In this way, arrangements where plate-like portions 33 of contact plugs WC aligned in X direction when transparently viewing from Z direction allow to easily decrease arrangement pitch in X direction between contact plugs WC.

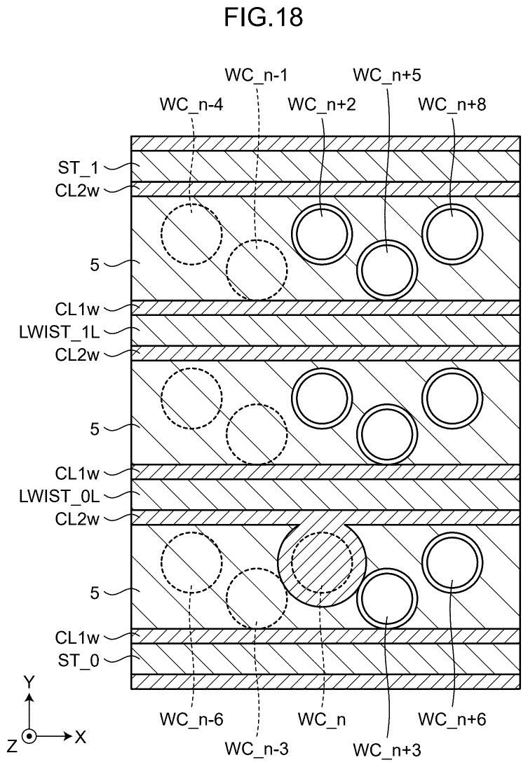

Alternatively, as a fourth modification of the embodiment, the contact plug WC as illustrated in FIG. 18 may be arranged in a staggered manner and the plate-like portions 33 of contact plugs WC as illustrated in FIG. 18 may overlap with each other when transparently viewing from Z direction. FIG. 18 is a plan view illustrating a configuration of the contact region WCR in the fourth modification of the embodiment.

The contact plugs WC aligned in X direction may be alternately connected to conductive lines CL on +Y-side side surface and on −Y-side side surface. The plate-like portion 33 of each contact plug WC overlaps with plate-like portion 33 of contact plug WC adjacent to it in X direction when transparently viewing from Z direction. The plate-like portion 33 of each contact plug WC may contact cylindrical portion 32 of contact plug WC adjacent to it in X direction.

In this way, arrangements where contact plugs WC aligned in X direction are arranged in a staggered manner and plate-like portions 33 overlaps with each other allow to easily decrease layout area of contact plug in contact region WCR and to easily decrease arrangement pitch in X direction of contact plugs WC.

Alternatively, the idea of the present embodiment may be applied to a staircase structure instead of the stepwise contact plug structure.

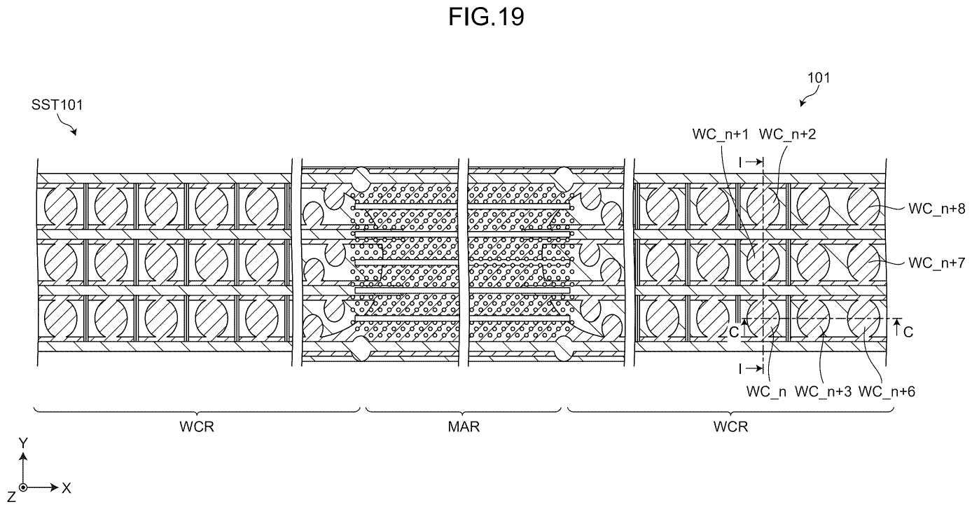

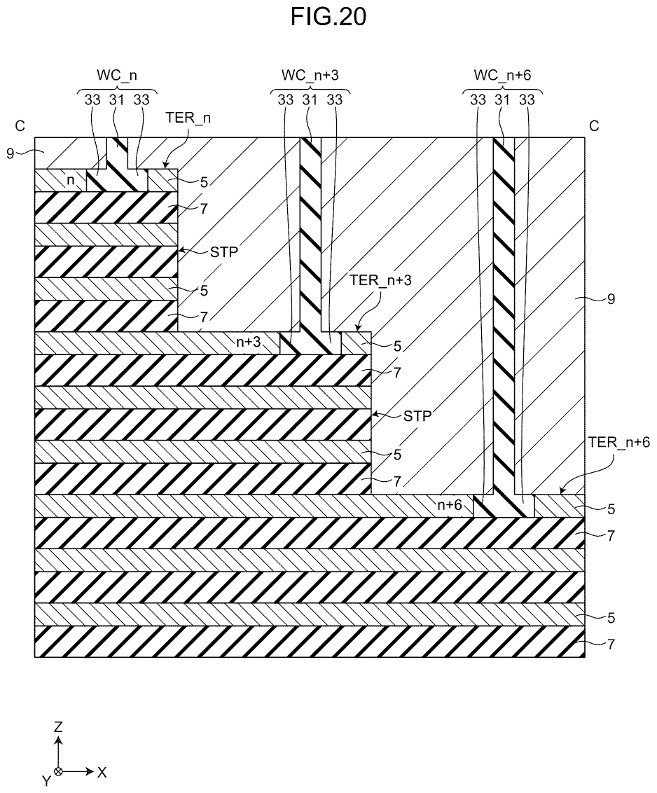

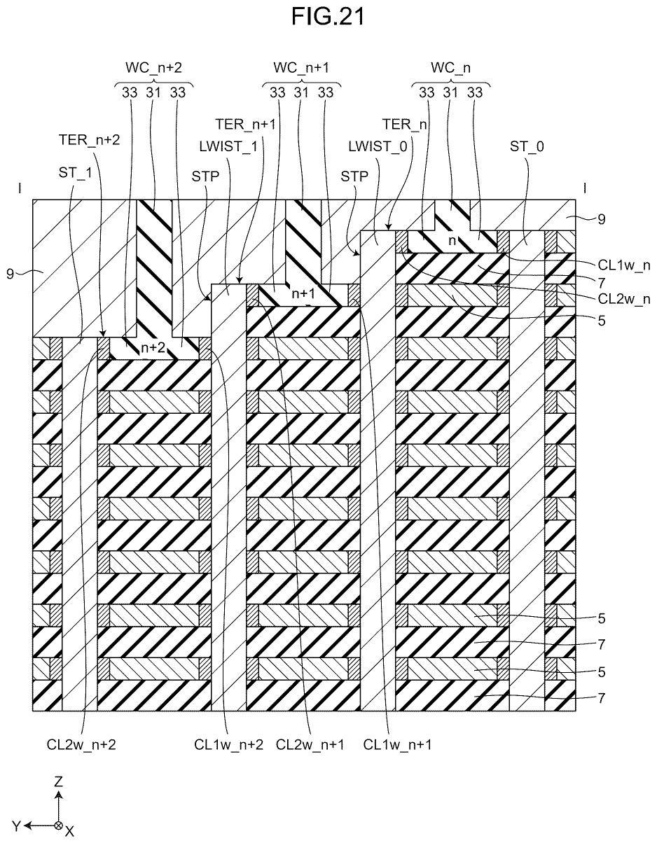

For example, as a fifth modification of the embodiment, the staircase structure as illustrated in FIGS. 19 to 21 may be provided in each contact region WCR of a stacked body SST100 of a semiconductor memory device 101. FIG. 19 is a plan view illustrating a schematic configuration of the stacked body SST100 in the fifth modification of the embodiment. FIGS. 20 and 21 are cross-sectional views each illustrating a configuration of the contact region WCR in the fifth modification of the embodiment. FIG. 20 illustrates an XZ cross section taken along line C-C in FIG. 19. FIG. 21 illustrates a YZ cross section taken along line I-I in FIG. 19.

In the semiconductor memory device 101, the staircase structure is provided in each contact region WCR. The staircase structure has a plurality of terrace portions TER and a plurality of step portions STP, and the +Z side thereof is covered with an interlayer insulating film 9. Each terrace portion TER is formed on a +Z-side surface of the insulating layer 5 at the Z position where the contact plug is to reach. Each step portion STP is formed with the number of steps corresponding to a difference in the Z position of the terrace portion TER adjacent in the XY direction. By the staircase structure, the insulating layer 5 is drawn out in a staircase shape.

For example, in a terrace portion TER_n, the insulating layer 5 corresponding to the conductive layer 6 (word line WL_n) is drawn out. The contact plug WC_n extends in the −Z direction from the +Z side of the stacked body SST100 and reaches the insulating layer 5 of the terrace portion TER_n.

In a terrace portion TER_n+1, the insulating layer 5 corresponding to the conductive layer 6 (word line WL_n+1) is drawn out. The contact plug WC_n+1 extends in the −Z direction from the +Z side of the stacked body SST100 and reaches the insulating layer 5 of the terrace portion TER_n+1.

In a terrace portion TER_n+6, the insulating layer 5 corresponding to the conductive layer 6 (word line WL_n+6) is drawn out. The contact plug WC_n+6 extends in the −Z direction from the +Z side of the stacked body SST100 and reaches the insulating layer 5 of the terrace portion TER_n+6.

In each contact plug, the cylindrical portion 32 is omitted, and the side surface of the columnar portion 31 is covered with the interlayer insulating film 9 from the outside in the XY direction.

For example, in the contact plug WC_n, the cylindrical portion 32 is omitted, and the side surface of the columnar portion 31 is covered with the interlayer insulating film 9 from the outside in the XY direction.

In the contact plug WC_n+1, the cylindrical portion 32 is omitted, and the side surface of the columnar portion 31 is covered with the interlayer insulating film 9 from the outside in the XY direction.

In the contact plug WC_n+6, the cylindrical portion 32 is omitted, and the side surface of the columnar portion 31 is covered with the interlayer insulating film 9 from the outside in the XY direction.

Note that, at the Z position of each terrace portion TER, both side surfaces of the plurality of contact plugs WC are connected to the two conductive lines CL1w and CL2w extending in the X direction along both side surfaces of the insulating layer 5, and are connected to the conductive layer 6 in the memory array region MAR via the two conductive lines CL1w and CL2w. This point is similar to the embodiment.

Even with the above structure, it is possible to structurally reinforce the plurality of insulating layers 7 in each contact region WCR while securing the signal transmission path from each contact region WCR to the memory array region MAR. In other words, in the stacked body SST100, the plurality of insulating layers 7 separated from each other in the Z direction can be structurally reinforced without additionally providing the insulating film HR as the reinforcing material. Therefore, it is possible to provide the semiconductor memory device 101 suitable for easily processing the contact plug.

Alternatively, although not illustrated, each stacked body SST may include the contact region WCR on one side in the X direction. Each stacked body SST may include the memory array region MAR on one side in the X direction in the XY planar view, and may include the contact region WCR on the other side in the X direction. In the contact region WCR, the staircase structure for electrically accessing the memory cell array 2 may be disposed.

Alternatively, as a sixth modification of the embodiment, a staircase structure as illustrated in FIG. 22 may be provided in the contact region WCR of a stacked body SST200 of a semiconductor memory device 201. FIG. 22 is a plan view illustrating a schematic configuration of the stacked body SST200.

The stacked body SST200 may include the contact region WCR in the vicinity of the center in the X direction in the XY plan view, and may include the memory array region MAR in the vicinity of both ends in the X direction. The memory cell array 2 is disposed in each memory array region MAR similarly to the embodiment. The staircase structure is provided in the contact region WCR similarly to the fifth modification of the embodiment. A specific configuration of the staircase structure may be similar to the configuration illustrated in FIGS. 20 and 21, or may be a configuration to which a staircase processing process of making a large number of steps with a small number of processing times is applied.

Note that, at the Z position of each terrace portion TER, both side surfaces of the plurality of contact plugs WC are connected to the two conductive lines CL1w and CL2w extending in the X direction along both side surfaces of the insulating layer 5, and are connected to the conductive layer 6 in the memory array region MAR via the two conductive lines CL1w and CL2w. This point is similar to the embodiment.

Even with the above structure, it is possible to structurally reinforce the plurality of insulating layers 7 in each contact region WCR while securing the signal transmission path from each contact region WCR to the memory array region MAR. In other words, in the stacked body SST200, the plurality of insulating layers 7 separated from each other in the Z direction can be structurally reinforced without additionally providing the insulating film HR as the reinforcing material. Therefore, it is possible to provide the semiconductor memory device 201 suitable for easily processing the contact plug.

Alternatively, as a seventh modification of the embodiment, the semiconductor memory device 1 may be manufactured as illustrated in FIGS. 23A to 41 and FIG. 7. FIGS. 23A to 41 and FIG. 7 illustrate a manufacturing method of a configuration in which the arrangement of the contact plugs in the contact region WCR is inverted in the X direction. Furthermore, an idea of the manufacturing method described with reference to FIGS. 23A to 41 and FIG. 7 is also applicable to the method of manufacturing the semiconductor memory device 101 and the method of manufacturing the semiconductor memory device 201.

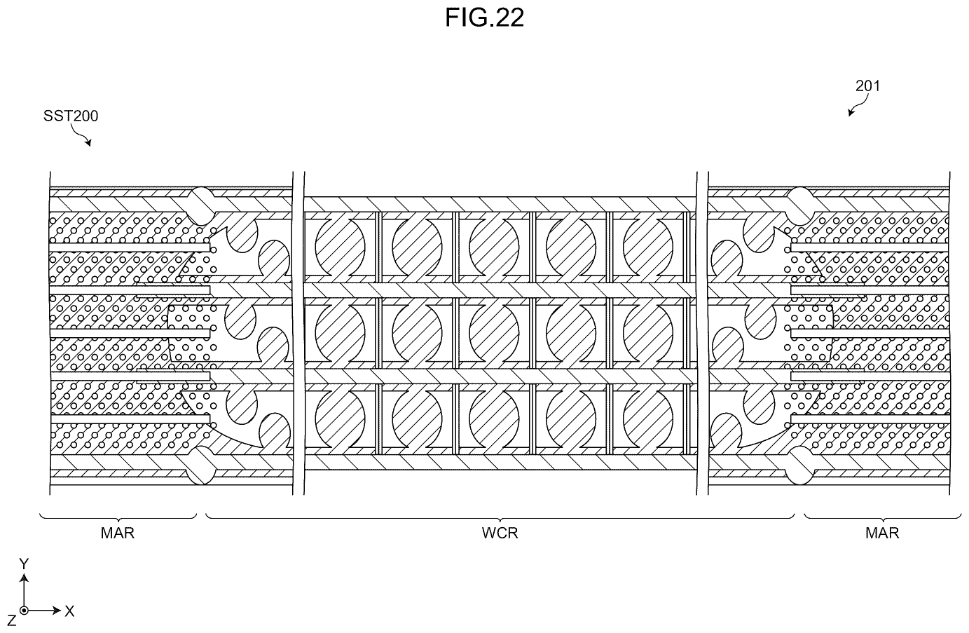

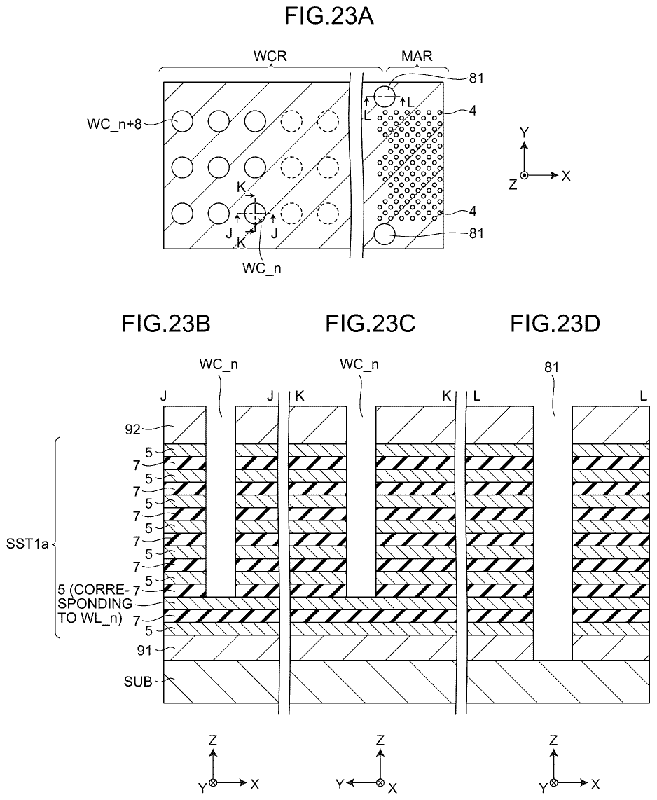

FIGS. 23A, 24A, 25A, 26A, 27A, 28A, 29A, 30A, 31A, 32A, 34A, 36A, 38A, and 40A are XY plan views illustrating a method of manufacturing the semiconductor memory device 1, respectively. FIG. 7 is the XY plan view illustrating a schematic configuration of the stacked body SST in the semiconductor memory device 1, but is used as an XY plan view illustrating a method of manufacturing the semiconductor memory device 1.

FIGS. 23B, 24B, 25B, 26B, 27B, 28B, 29B, 30B, 31B, 32B, 34B, 36B, 38B, and 40B are XZ cross-sectional views illustrating the method of manufacturing the semiconductor memory device 1, respectively.

FIGS. 23B, 24B, 25B, 26B, 27B, 28B, 29B, 30B, 31B, 32B, 34B, 36B, 38B, and 40B are XZ cross-sectional views respectively taken along lines J-J, M-M, P-P, S-S, VV, Y-Y, BB-BB, EE-EE, HH-HH, KK-KK, OO-OO, SS-SS, ZZ-ZZ, and DDD-DDD in FIGS. 23A, 24A, 25A, 26A, 27A, 28A, 29A, 30A, 31A, 32A, 34A, 36A, 38A, and 40A.

FIGS. 23C, 24C, 25C, 26C, 27C, 28C, 29C, 30C, 31C, 32C, 34C, 36C, 38C, and 40C are YZ cross-sectional views illustrating the method of manufacturing the semiconductor memory device 1, respectively.

FIGS. 23C, 24C, 25C, 26C, 27C, 28C, 29C, 30C, 31C, 32C, 34C, 36C, 38C, 38C, and 40C are YZ cross-sectional views respectively taken along lines K-K, N-N, Q-Q, T-T, W-W, Z-Z, CC-CC, FF-FF, II-II, LL-LL, PP-PP, TT-TT, AAA-AAA, and EEE-EEE in FIGS. 23A, 24A, 25A, 26A, 27A, 28A, 29A, 30A, 31A, 32A, 34A, 36A, 38A, and FIG. 40A.

FIGS. 23D, 24D, 25D, 26D, 27D, 28D, 29D, 30D, 31D, 32D, 34D, 36D, 38D, and 40D are XZ cross-sectional views illustrating the method of manufacturing the semiconductor memory device 1, respectively.

FIGS. 23D, 24D, 25D, 26D, 27D, 28D, 29D, 30D, 31D, 32D, 34D, 36D, 38D, 38D, and 40D are XZ cross sectional views respectively taken along lines L-L, O-O, RR, U-U, X-X, AA-AA, DD-DD, GG-GG, JJ-JJ, MM-MM, QQ-QQ, UU-UU, BBB-BBB, and FFF-FFF in FIGS. 23A, 24A, 25A, 26A, 27A, 28A, 29A, 30A, 31A, 32A, 34A, 36A, 38A, and 40A.

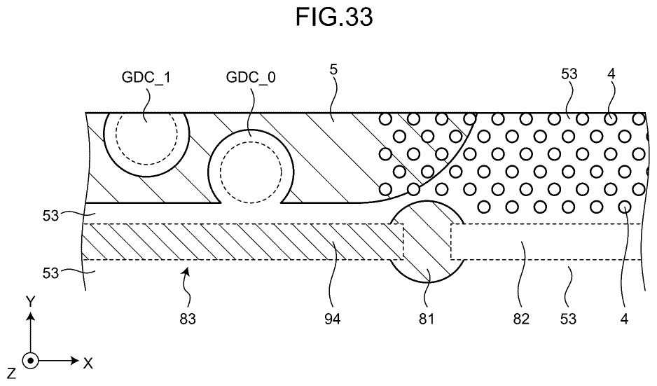

FIGS. 33, 35, 37, 39, and 41 are enlarged XY plan views illustrating the method of manufacturing the semiconductor memory device 1, respectively.

FIGS. 33, 35, 37, 39, and 41 are enlarged XY plan views of an NN portion, an RR portion, a VV portion, a CCC portion, and a GGG portion in FIGS. 23A, 24A, 25A, 26A, 27A, 28A, 29A, 30A, 31A, 32A, 34A, 36A, 38A, and 40A, respectively.

In the steps illustrated in FIGS. 23A to 23D, a transistor is formed on the substrate SUB, a contact plug, a wiring film, a via plug, and the like are formed on the substrate SUB, and an interlayer insulating film is formed around the contact plug, the wiring film, the via plug, and the like. As a result, a peripheral circuit 100 is formed. Thereafter, the interlayer insulating film 91 is deposited on the +Z side of the substrate SUB. The interlayer insulating film 91 can be formed of a material containing an insulator (e.g., semiconductor oxide such as silicon oxide) as a main component. The conductive layer 3 (source line SL) is deposited on the +Z side of the interlayer insulating film 91. The conductive layer 3 may be formed of a material containing a semiconductor (e.g., silicon) containing impurities as a main component or a material containing a conductive material (e.g., metal such as tungsten) as a main component. The insulating layer 5 and the insulating layer 7 are alternately deposited a plurality of times on the +Z side of the conductive layer 3 to form a stacked structure SST1a. The insulating layer 5 may be made of a material containing a nitride (e.g., silicon nitride) as a main component. The insulating layer 7 may be made of a material containing an oxide (e.g., silicon oxide) as a main component. Each insulating layer 5 and each insulating layer 7 can be deposited with substantially the same film thickness. The stacked structure SST1a includes a memory array region MAR near the center in the X direction in the XY plan view and includes the contact regions WCR near both ends in the X direction. An interlayer insulating film 92 is deposited on the +Z side of the stacked structure SST1a.

A resist pattern in which a formation position of a memory hole in the memory array region MAR is opened is formed on the stacked structure SST1a, and anisotropic dry etching is performed using the resist pattern as a mask. The tunnel insulating film 431, the charge storage film 432, the block insulating film 433, the semiconductor film 42, and the core insulating film 41 are sequentially deposited in a memory hole (see FIG. 5), and the columnar body 4 is formed in the memory array region MAR.

Thereafter, a contact processing process of making many stages with a small number of processing times is applied to the contact region WCR of the stacked structure SST1a to form the stepwise contact hole structure. In the contact processing process, formation of a resist pattern having an opening at a position where a contact hole is to be arranged and anisotropic dry etching using the resist pattern as a mask are alternately repeated a plurality of times. At this time, by using a resist pattern having different opening positions each time of repetition, many stages can be created with a small number of processing times. As a result, in the contact region WCR, the stepwise contact hole structure in which a plurality of contact holes having different depths stepwise is formed.

FIG. 23A illustrates a state in which a plurality of contact holes WC_n to WC_n+8 is formed. The plurality of contact holes WC_n to WC_n+8 has different depths. The plurality of contact holes WC_n to WC_n+8 reaches the insulating layers 5 corresponding to the conductive layer 6 (word lines WL_n) to the conductive layer 6 (word lines WL_n+8), respectively.

At the same time, a resist pattern RG1 having an opening at a position where a columnar insulator 81 to be a part of the slit ST to be disposed is formed in the vicinity of the boundary between the contact region WCR and the memory array region MAR in the stacked structure SST1a, and anisotropic dry etching is performed using the resist pattern RG1 as a mask until the resist pattern RG1 reaches the surface of the substrate SUB. Thus, a hole 81 reaching the surface of the substrate SUB is formed.

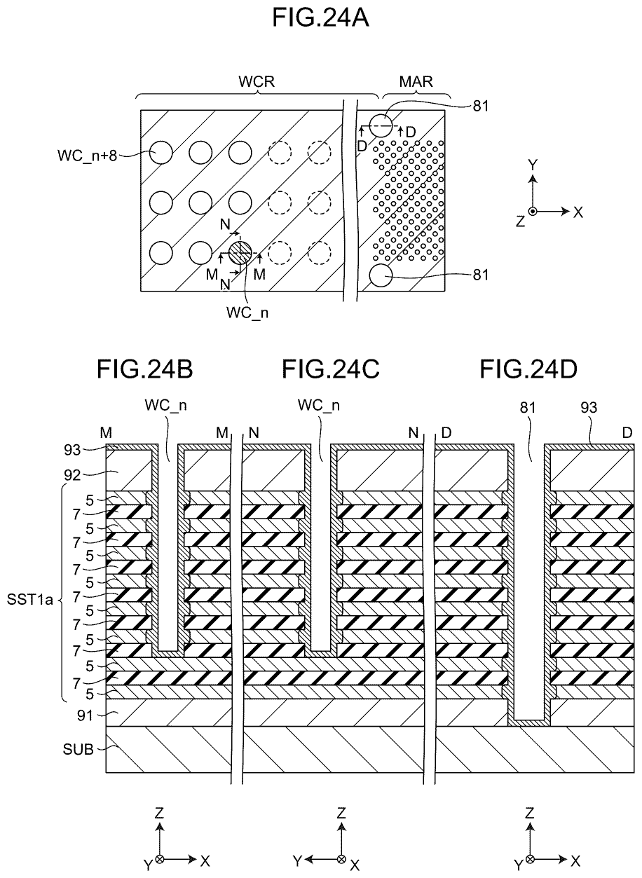

In the steps illustrated in FIGS. 24A to 24D, a barrier insulating film 93 is formed so as to entirely cover an exposed surface. The barrier insulating film 93 may be formed by plasma isotropic oxidation (PIO). For example, a nitride film (e.g., silicon nitride film) is deposited so as to entirely cover the exposed surface. The nitride film entirely covering the exposed surface is subjected to plasma oxidation treatment, and the nitride film becomes an oxide film (e.g., silicon oxide film). As a result, an oxide film can be formed as the barrier insulating film 93.

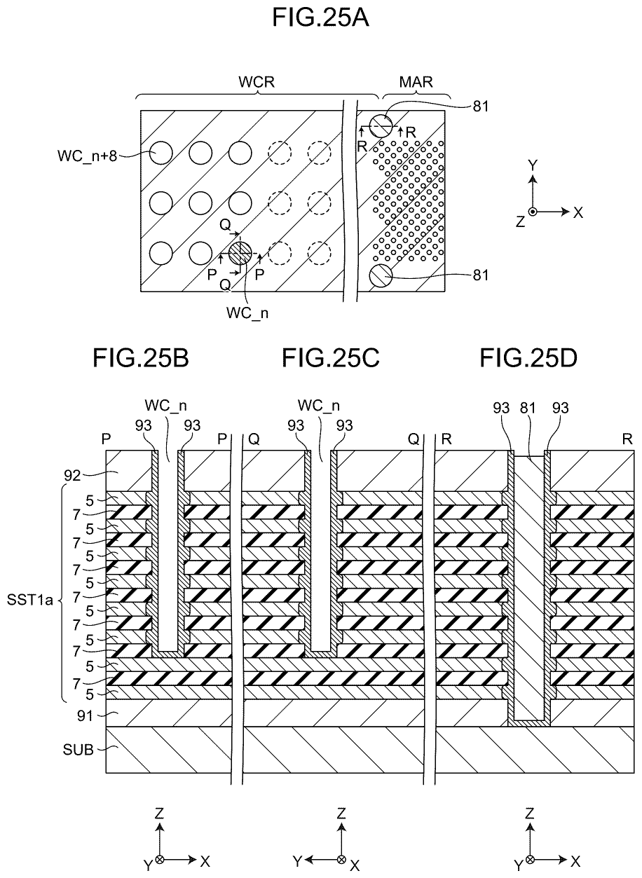

In the steps illustrated in FIGS. 25A and 25B, a portion covering the +Z-side surface of an interlayer insulating film 92 in the barrier insulating film 93 entirely covering the exposed surface is selectively removed by dry etching or wet etching. As a result, the barrier insulating film 93 remains on an inner side surface and a bottom surface of each of the contact holes WC_n to WC_n+8 and the hole 81.

Thereafter, an insulator is embedded in the hole 81. As a result, the columnar insulator 81 that will be a part of the slit ST is formed.

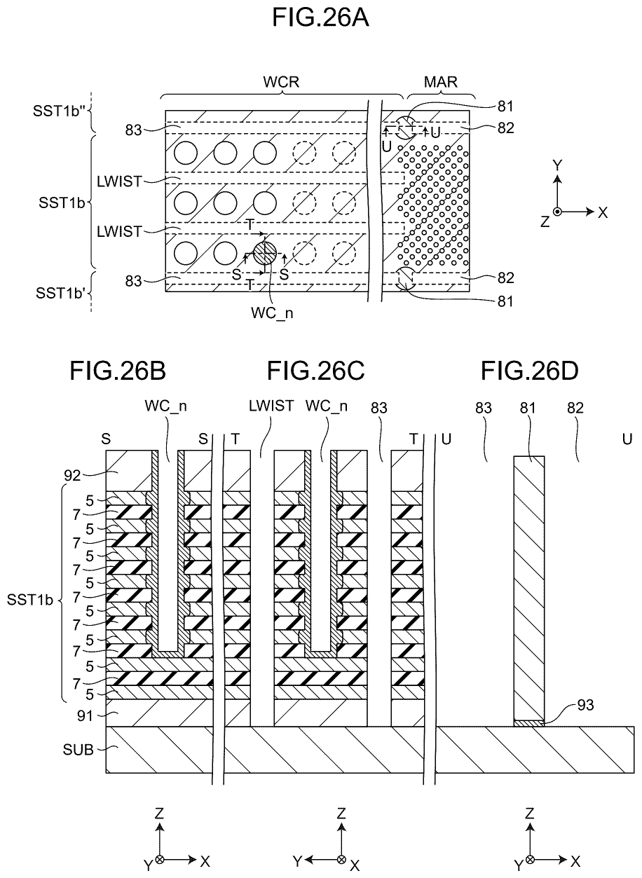

In the steps illustrated in FIGS. 26A to 26D, a resist pattern RG2 having an opening at a position where the insulating films 82 and 83 that will be another part of the slit ST and the insulating film LWIST will be disposed is formed, and anisotropic dry etching is performed using the resist pattern RG2 as a mask until the resist pattern RG2 reaches the surface of the substrate SUB. As a result, the opening 82 and the opening 83 extending in the X direction, penetrating the stacked structure SSTa, and reaching the surface of the substrate SUB are formed on both sides in the X direction of the columnar insulator 81, and the opening LWIST extending in the X direction, penetrating the stacked structure SSTa, and reaching the surface of the substrate SUB is formed between the two openings 83 in the Y direction. As a result, the stacked structure SST1a is divided into a plurality of stacked bodies SST1b′, SST1b, and SST1b″. The stacked bodies SST1b′, SST1b, and SST1b″ are arranged in the Y direction, and each has a substantially rectangular shape in which the X direction is a longitudinal direction in the XY plan view. At this time, the barrier insulating films 93 on both side surfaces in the X direction of the columnar insulator 81 are removed, and both side surfaces in the X direction of the columnar insulator 81 can be exposed to the opening 82 and the opening 83.

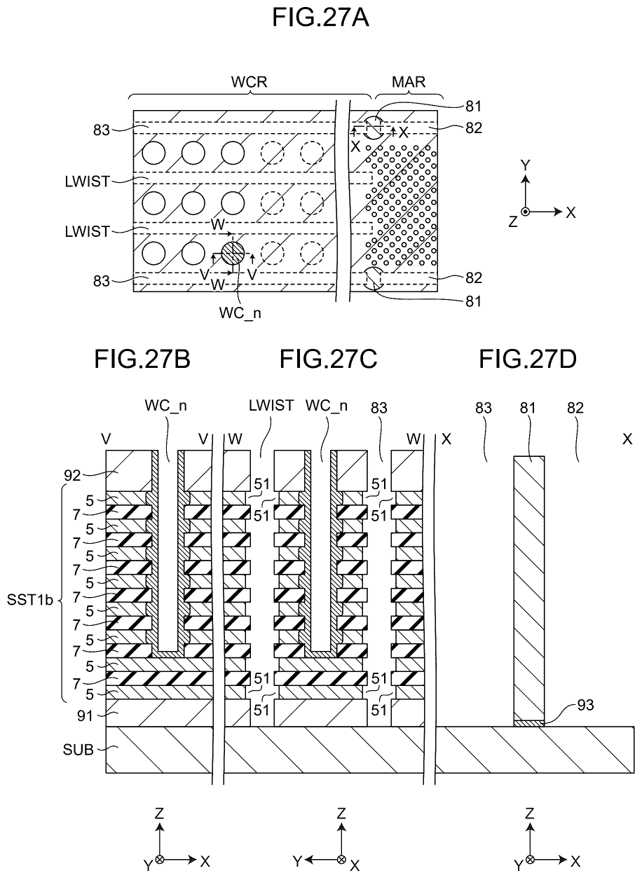

In the steps illustrated in FIGS. 27A to 27D, a slimming process of etching and retracting the side surface of the insulating layer 5 exposed at the opening LWIST and the opening 83 is performed. A recess 51 is formed on each of the opening LWIST and the inner side surface of the opening 83 by the slimming process. The recess 51 is formed so as to be recessed in a direction away from the center of the opening LWIST and the opening 83, with respect to the opening LWIST and the inner side surface of the opening 83, at the Z position of each insulating layer 5 in the stacked body SST1b. For example, the opening LWIST and the inner side surface of the opening 83 are wet-etched using an etchant having a high etching selectivity of the insulating layer 5 to the insulating layer 7 and the interlayer insulating films 91 and 92. Alternatively, the opening LWIST and the inner surface of the opening 83 are dry-etched under the condition of isotropic etching using a processing gas having a high etching selectivity of the insulating layer 5 to the insulating layer 7 and the interlayer insulating films 91 and 92. As a result, the side surfaces of the insulating layer 5 exposed at the opening LWIST and the opening 83 are etched and retracted, and the recess 51 can be formed on the inner side surfaces of the opening LWIST and the opening 83. The recess width (recess amount) of the recess 51 with respect to the opening LWIST and the inner side surface of the opening 83 can be adjusted by etching time. The width of the recess 51 in the Z direction is substantially substantially equal to the thickness of the insulating layer 5.

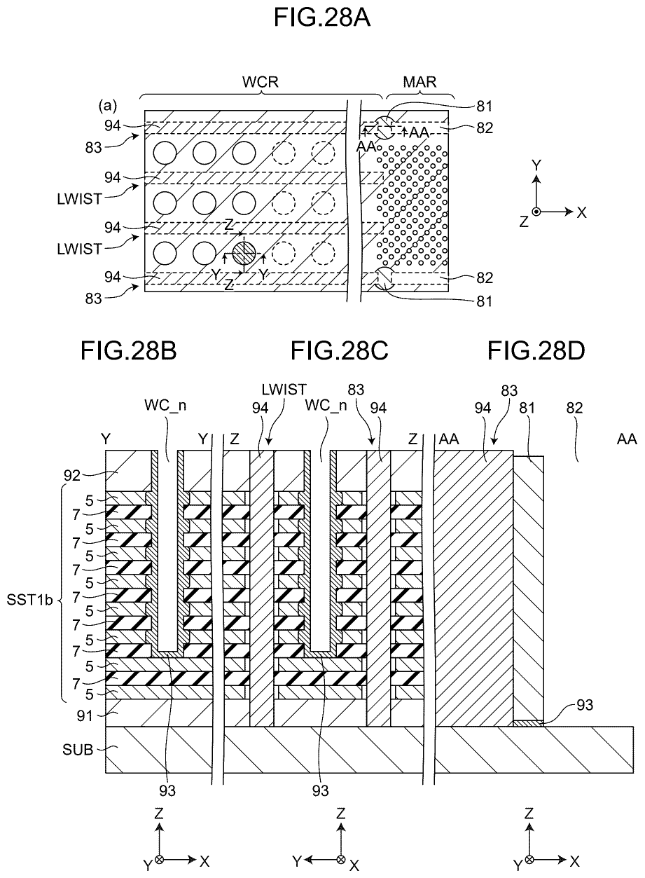

In the steps illustrated in FIGS. 28A to 28D, a sacrificial film 94 is embedded in the opening LWIST and the opening 83. The sacrificial film 94 can be formed of any material having etching resistance to an etchant (e.g., phosphoric acid) of the insulating layer 5. The sacrificial film 94 may be made of amorphous silicon.

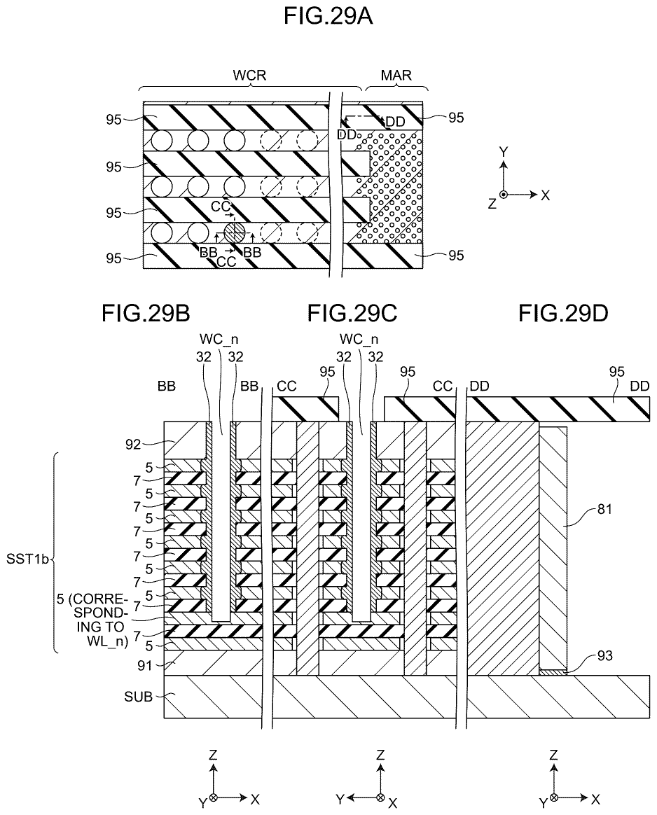

In the steps illustrated in FIGS. 29A to 29D, a protective film 95 is entirely deposited. The protective film 95 can be formed of any material having etching resistance to the etchant of the insulating layer 5. As the protective film 95, silane (p-SiH₄) formed by a plasma CVD method or the like may be used. A resist pattern RG3 selectively covering the insulating columnar 81, the opening 82, the opening 83, and the opening LWIST is formed on the protective film 95, and etching is performed using the resist pattern RG3 as a mask until the interlayer insulating film 92 is exposed. As a result, the protective film 95 that selectively covers the insulating columnar 81, the opening 82, the opening 83, and the opening LWIST is formed. At this time, the insulating barrier film 93 covering the bottom surface of the contact hole WC is also etched, and the bottom surface of the contact hole WC can be etched to the inside of the insulating layer 5 corresponding to the conductive layer 6 (word line WL_n). As a result, the insulating barrier film 93 remains on the inner side surface of the contact hole WC, and the cylindrical portion 32 that will a part of the contact plug WC is formed.

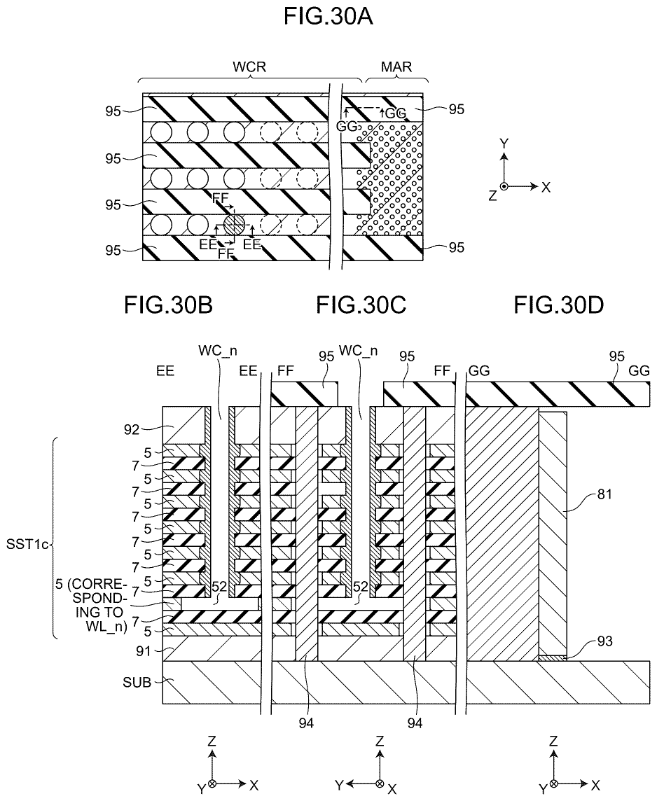

In the steps illustrated in FIGS. 30A to 30D, the insulating layer 5 exposed at the bottom surface of the contact hole WC is wet etched using the etchant for the insulating layer 5. As a result, a gap 52 that will be the plate-like portion 33 (see FIGS. 9C and 10) of the contact plug WC is formed. The gap 52 can be formed in a substantially disk shape with an XY plane dimension larger than the contact hole WC.

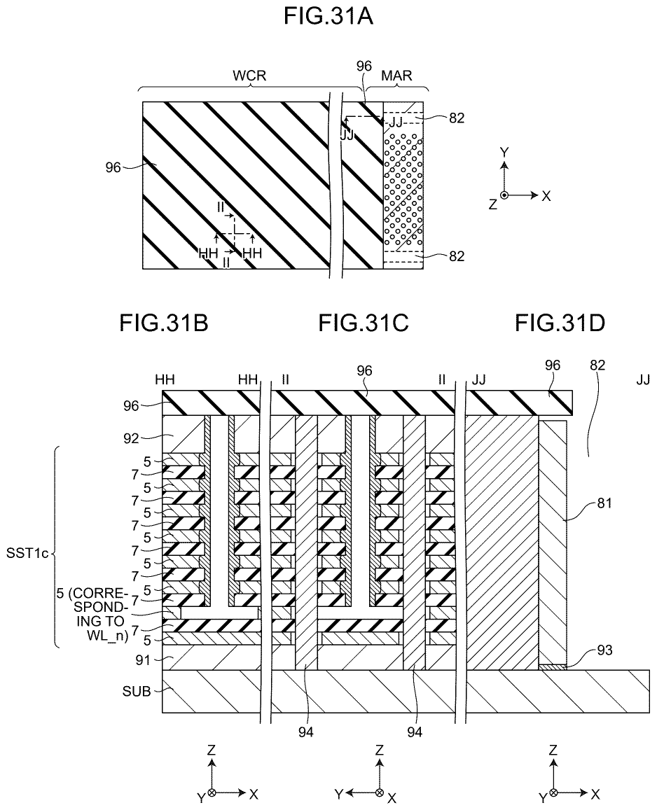

In the steps illustrated in FIGS. 31A to 31D, the protective film 95 is removed by performing wet etching using the etchant of the protective film 95.

Thereafter, a protective film 96 is entirely deposited. The protective film 96 can be formed of any material having etching resistance to the etchant of the insulating layer 5. As the protective film 96, silane (p-SiH4) formed by a plasma CVD method or the like may be used. A resist pattern RG4 selectively covering the contact region WCR is formed on the protective film 96, and etching is performed using the resist pattern RG4 as a mask until the interlayer insulating film 92 is exposed. As a result, the protective film 96 that selectively covers the contact region WCR is formed.

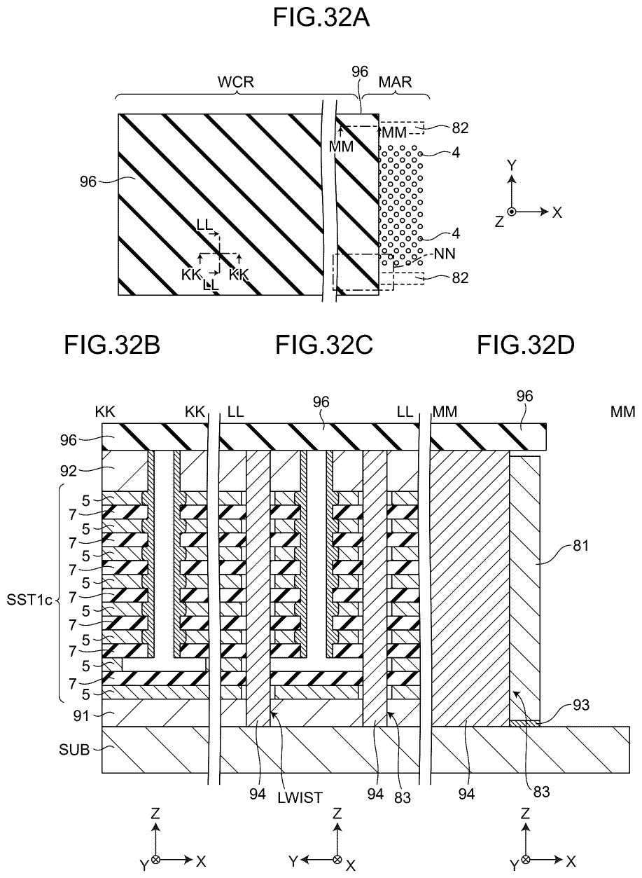

In the steps illustrated in FIGS. 32A to 32D, and 33, wet etching is performed using the etchant for the insulating layer 5 (e.g., phosphoric acid). The etchant reaches the insulating layer 5 from the opening 82, and the insulating layer 5 in the memory array region MAR is etched. As a result, in the memory array region MAR, a gap 53 in which the conductive layer 6 will be embedded is mainly formed around the XY direction of the columnar body 4.

At this time, the contact region WCR is covered with the protective film 96. The columnar insulator 81 is interposed between the opening 82 and the opening 83, and the sacrificial film 94 is embedded in the opening 83 and the opening LWIST. In other words, the protective film 96, the columnar insulator 81, and the sacrificial film 94 function as etching stoppers, and some of the gaps 53 may also be formed in the contact region WCR as illustrated in FIG. 33, but most of the insulating layer 5 in the contact region WCR remains without being etched.

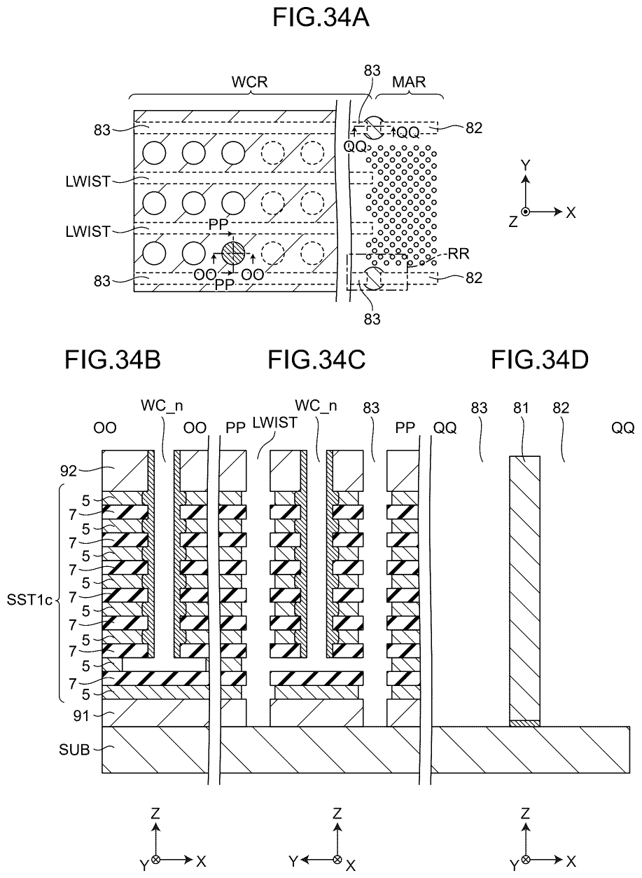

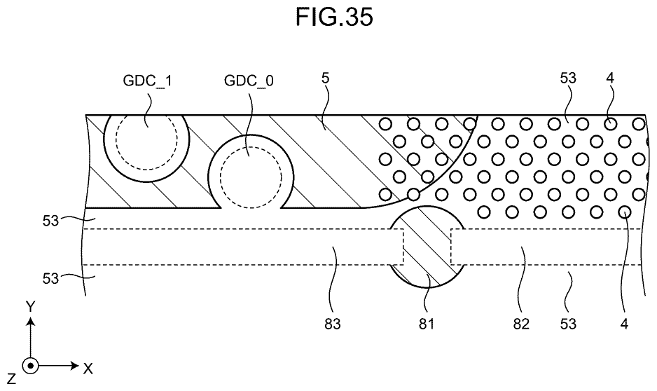

In the steps illustrated in FIGS. 34A to 34D, and 35, the protective film 96 is removed by performing wet etching using the etchant of the protective film 96.

Thereafter, wet etching is performed using the etchant of the sacrificial film 94, and the sacrificial film 94 is removed from the opening LWIST and the opening 83.

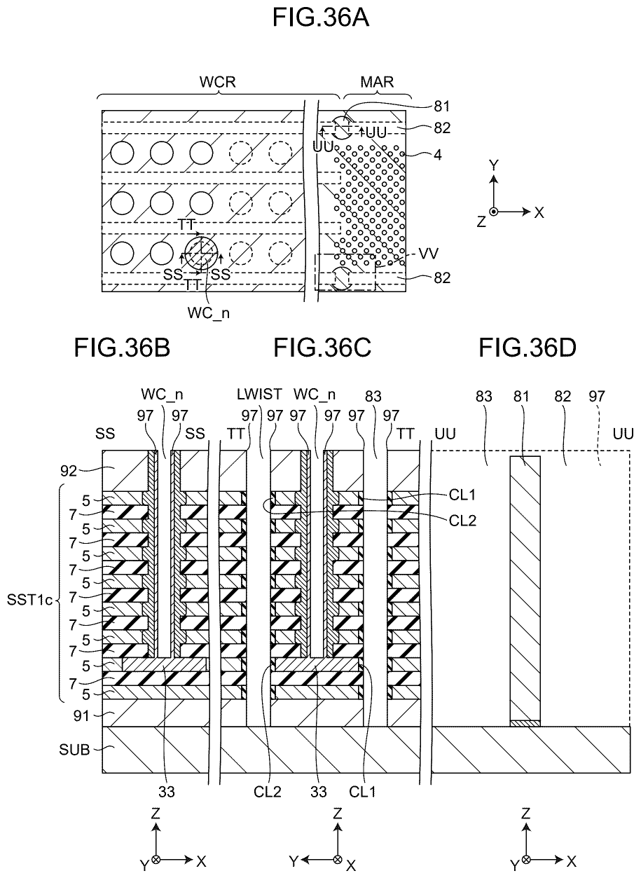

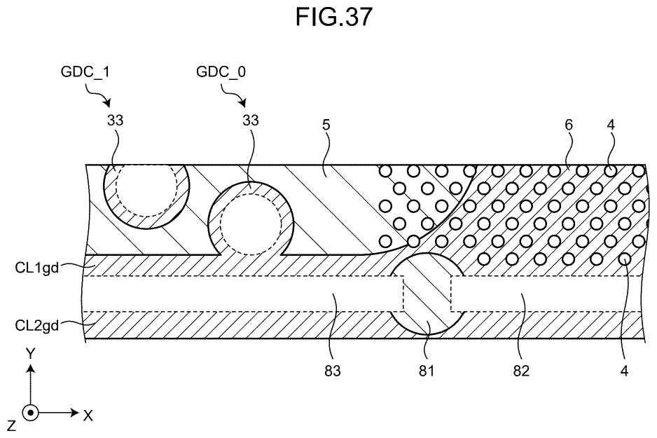

In the steps illustrated in FIGS. 36A to 36D, and 37, a conductive film 97 is entirely introduced. The conductive film 97 can be formed of a material containing a conductive material (e.g., metal such as tungsten) as a main component.

In the contact region WCR, the gap 52 is filled with the conductive film 97 via the contact hole WC. Thus, the plate-like portion 33 that will be a part of the contact plug WC is formed. At this time, the conductive film 97 is deposited on the inner side surface of the contact hole WC. In addition, the recess 51 (see FIG. 27) is filled with the conductive film 97 via the opening 83 and the opening LWIST. As a result, the conductive lines CL1 and CL2 extending in the X direction along the inner side surfaces of the opening 83 and the opening LWIST are formed at the Z position of each insulating layer 5. At this time, the conductive film 97 is deposited on the inner side surfaces of the opening 83 and the opening LWIST.

In the memory array region MAR, the gap 53 (see FIG. 35) is filled with the conductive film 97 via the opening 82. As a result, as illustrated in FIG. 37, the conductive layer 6 is formed around the columnar body 4 in the XY direction. At this time, as indicated by a dotted line in FIG. 36D, the conductive film 97 is deposited on the inner side surface of the opening 82.

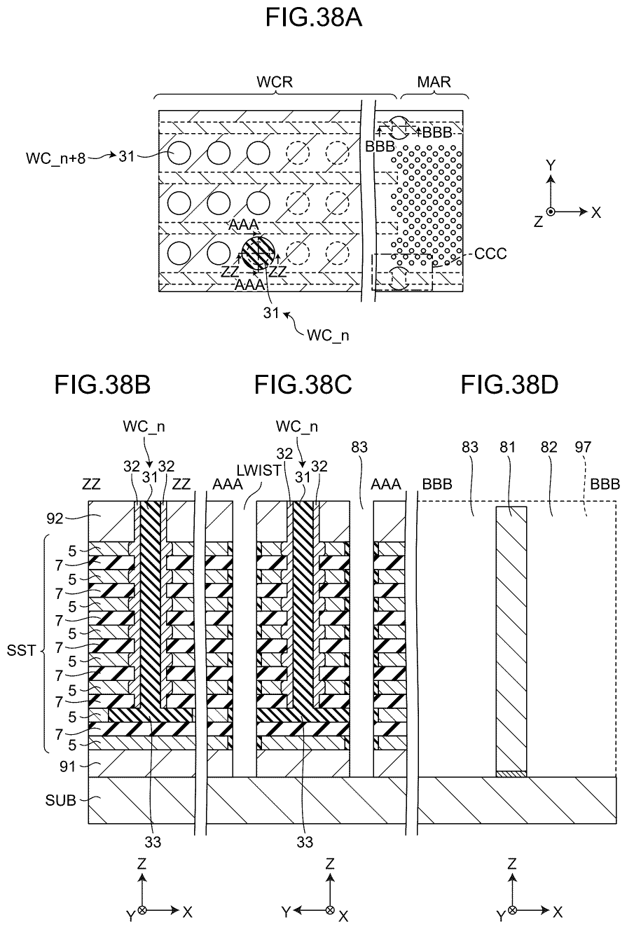

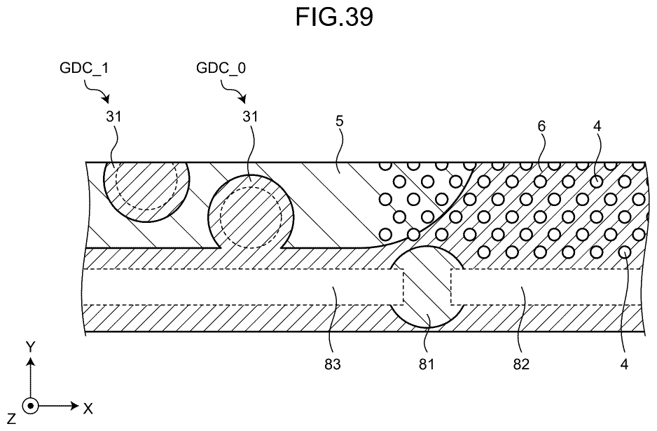

In the steps illustrated in FIGS. 38A to 38D, and 39, the conductive film 97 is embedded in the contact hole. As a result, the columnar portion 31 that will be a part of the contact plugs WC and GDC is formed. In other words, the contact plugs WC and GDC including the columnar portion 31, the cylindrical portion 32, and the plate-like portion 33 are formed.

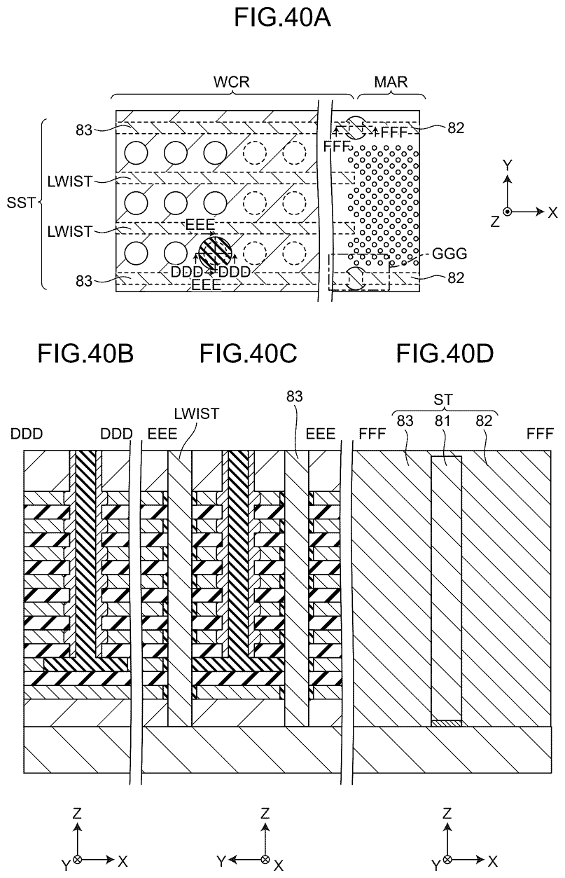

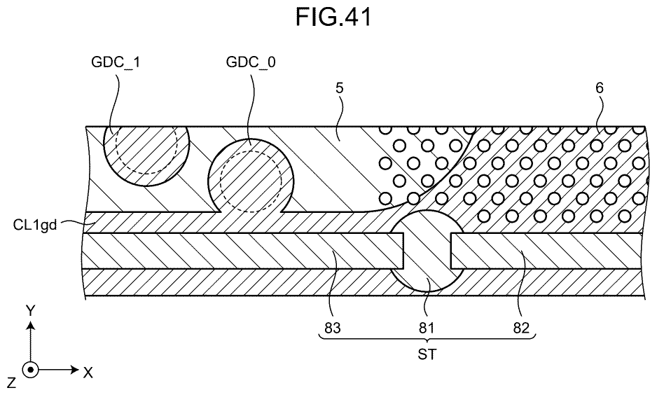

In the steps illustrated in FIGS. 40A to 40D, and 41, the conductive film 97 is removed from inner side surfaces of the opening 82, the opening 83, and the opening LWIST such that the conductive film 97 remains in the recess 51 (see FIG. 27) via the opening 83 and the opening LWIST by performing wet etching using the etchant of the conductive film 97.

Thereafter, an insulator (e.g., silicon oxide) is embedded in the opening 82, the opening 83, and the opening LWIST. As a result, the insulating film 82, the insulating film 83, and the insulating film LWIST are formed. In other words, the slits ST including the columnar insulator 81, the insulating film 82, and the insulating film 83 are formed on both side surfaces in the Y direction of the stacked body SST, and the insulating film LWIST is formed between the two slits ST in the Y direction.

In the process illustrated in FIG. 7, a resist pattern RG5 having an opening at a position where the insulating film SHE will be disposed in the memory array region MAR is formed, and anisotropic dry etching is performed using the resist pattern RG5 as a mask until reaching the Z position between the conductive layer 6 (selection gate line SGD) and the conductive layer 6 (word line WL_0). As a result, the opening SHE extending to the XY position overlapping the insulating film LWIST in the X direction and reaching the Z position between the conductive layer 6 (selection gate line SGD) and the conductive layer 6 (word line WL_0) is formed.

Then, an insulator (e.g., silicon oxide) is embedded in the opening SHE. As a result, a plurality of insulating films SHE that partition the memory array region MAR into a plurality of independently controllable regions arranged in the Y direction are formed.

In this manner, the semiconductor memory device 1 can be manufactured by the manufacturing processes illustrated in FIGS. 23A to 41 and FIG. 7.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

What is claimed is:

1. A semiconductor memory device comprising:
a stacked body including a first region and a second region adjacent to the first region in a first direction, the first region having a plurality of conductive layers stacked, via a first insulating layer, in a third direction intersecting the first direction and a second direction, the second region having a plurality of second insulating layers stacked, via the first insulating layer, in the third direction;
a semiconductor film extending in the third direction in the first region;
a charge storage film extending in the third direction between the plurality of conductive layers and the semiconductor film in the first region;
a plurality of contact plugs corresponding to the plurality of second insulating layers, each of the contact plugs extending in the third direction in the second region and reaching a stacking position of a corresponding second insulating layer among the second insulating layers;
a plurality of first conductive lines corresponding to the plurality of second insulating layers, each of the first conductive lines extending in the first direction in the second region along a first side surface of a corresponding second insulating layer among the second insulating layers; and
a plurality of second conductive lines corresponding to the plurality of second insulating layers, each of the second conductive lines extending in the first direction in the second region along a second side surface of a corresponding second insulating layer among the second insulating layers, the second side surface being a surface on an opposite side of the first side surface.

2. The semiconductor memory device according to claim 1, wherein
in the second region, each of the plurality of contact plugs extends in the third direction in the plurality of second insulating layers.

3. The semiconductor memory device according to claim 2, wherein
the plurality of contact plugs has different depths stepwise.

4. The semiconductor memory device according to claim 1, wherein
the plurality of second insulating layers is formed in a stepwise manner in the second region,
the plurality of second insulating layers formed in the stepwise manner is covered with a fourth insulating layer, and
in the second region, each of the plurality of contact plugs extends in the third direction in the fourth insulating layer.

5. The semiconductor memory device according to claim 4, wherein
the second region is adjacent to the first region on one side in the first direction.

6. The semiconductor memory device according to claim 4, wherein
the second region is adjacent to the first region on both sides in the first direction.

7. The semiconductor memory device according to claim 1, wherein
the plurality of first conductive lines corresponds to the plurality of conductive layers,
each of the first conductive lines is connected to a respective side surface of the plurality of contact plugs exposed on the first side surface of the corresponding second insulating layer in the second region, and is connected to an end portion of a corresponding first conductive layer at a boundary between the first region and the second region,
the plurality of second conductive lines corresponds to the plurality of conductive layers, and
each of the second conductive lines is connected to a respective side surface of the plurality of contact plugs exposed on the second side surface of the corresponding second insulating layer in the second region, and is connected to an end portion of a corresponding second conductive layer at a boundary between the first region and the second region.

8. The semiconductor memory device according to claim 1, wherein
the plurality of conductive layers includes a conductive layer corresponding to a word line and a conductive layer corresponding to a selection gate line, and
a second contact plug is further included, the second contact plug corresponding to the conductive layer corresponding to a selection gate, extending in the third direction in the second region, and having a side surface connected to one of the first conductive line and the second conductive line.

9. The semiconductor memory device according to claim 8, wherein
the side surface of the second contact plug is spaced apart from an other of the first conductive line and the second conductive line.

10. The semiconductor memory device according to claim 8, wherein
the second contact plug is shallower in depth than the plurality of contact plugs.

11. The semiconductor memory device according to claim 8, further comprising:
a division film that divides the conductive layer corresponding to the selection gate line in the second direction and extends in the first direction and the third direction; and
a first insulating film disposed at a position toward the second direction from a side surface of the stacked body in the second region, the first insulating film extending in the first direction and the third direction, wherein
the division film and the first insulating film divide the stacked body into a plurality of string units aligned in the second direction and extending in the first direction and the third direction.

12. The semiconductor memory device according to claim 1, further comprising:
a first insulating film disposed at a position toward the second direction from a side surface of the stacked body in the second region, the first insulating film extending in the first direction and the third direction, wherein
each of the plurality of first conductive lines extends in the first direction between the corresponding second insulating layer and the first insulating film in the second region.

13. The semiconductor memory device according to claim 1, further comprising:
a second insulating film that covers a side surface of the stacked body in the first region, the second insulating film extending in the first direction and the third direction;
a third insulating film that covers a side surface of the stacked body in the second region, the third insulating film extending in the first direction and the third direction; and
a columnar insulator that extends in the third direction between the second insulating film and the third insulating film.

14. The semiconductor memory device according to claim 13, further comprising:
a first insulating film disposed at a position toward the second direction from a side surface of the stacked body in the second region, the first insulating film extending in the first direction and the third direction, wherein
in the second region, each of the plurality of first conductive lines extends in the first direction between the corresponding second insulating layer and the first insulating film or the third insulating film, and
in the second region, each of the plurality of second conductive lines extends in the first direction between the corresponding second insulating layer and the first insulating film or the third insulating film.

15. A method of manufacturing a semiconductor memory device comprising:
alternately stacking a first insulating layer and a second insulating layer a plurality of times and forming a stacked structure having a first region and a second region adjacent to the first region in a first direction;
forming a first opening and a second opening and dividing the stacked structure into a plurality of stacked bodies, the first opening penetrating the stacked structure in a third direction intersecting the first direction and the second direction and continuing in the first direction in the first region, the second opening penetrating the stacked structure in the third direction and continuing in the first direction in the second region; and
slimming the second insulating layer exposed on inner side surfaces of the first opening and the second opening and forming a recess on the inner side surfaces of the first opening and the second opening.

16. The method of manufacturing a semiconductor memory device according to claim 15, further comprising:
embedding a first sacrificial film in the first opening and embedding a second sacrificial film in the second opening after the slimming.

17. The method of manufacturing a semiconductor memory device according to claim 16, further comprising:
forming a plurality of contact holes reaching a corresponding second insulating layer among a plurality of the second insulating layers in the second region of the stacked structure after the forming the stacked structure and before the dividing the stacked structure;
forming a first protective film selectively covering the first opening and the second opening after the embedding; and
removing the plurality of second insulating layers that the plurality of contact holes respectively reaches in a state that the first opening and the second opening are covered with the first protective film.

18. The method of manufacturing a semiconductor memory device according to claim 17, further comprising:
removing the first protective film and forming a second protective film selectively covering the second region; and
removing the second insulating layer in the first region in a state that the second region is covered with the second protective film.

19. The method of manufacturing a semiconductor memory device according to claim 18, further comprising:
removing the second protective film, embedding a first conductive film in the plurality of contact holes, embedding a second conductive film in the first opening, and embedding a third conductive film in the second opening;
removing the first conductive film and the second conductive film from the inner side surfaces of the first opening and the second opening while the first conductive film and the second conductive film remain in the recess on the inner side surfaces of the first opening and the second opening; and
embedding a first insulating film in the first opening and embedding a second insulating film in the second opening.

20. The method of manufacturing a semiconductor memory device according to claim 15, further comprising:
forming a third opening penetrating the stacked structure in the third direction near a boundary between the first region and the second region after the forming and before the dividing the stacked structure; and
embedding an insulator in the third opening and forming a columnar insulator, wherein
the dividing includes forming the first opening and the second opening on both sides of the columnar insulator in the first direction and dividing the stacked structure into the plurality of stacked bodies.
